(19) United States
(12) Patent Application Publication
(10) Pub. No.: US 2004/0237896 A1
(43) Pub. Date: Dec. 2, 2004

(54) Plating apparatus

(76) Inventor: Akihisa Hongo, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/483,883

(22) PCT Filed: Jul. 17, 2002
(86) PCT No.: PCT/JP02/07247

(30) Foreign Application Priority Data
Jul. 18, 2001 (JP) 2001-218343

(51) Int. Cl. C23C 16/00

(52) U.S. Cl. 118/719

(57) ABSTRACT

A plating apparatus for plating a substrate comprises a processing section (12) defined in a clean room, processing units (5, 6) disposed within the processing section (12) for processing the substrate, a plating section (14) defined in the processing section (12), and a plating unit (4) disposed within the plating section (14) for plating the substrate (W). Air can be supplied to and discharged from the plating section (14) independently of the processing section (12) outside of the plating section (14). The plating apparatus further comprises a partition wall (10) for isolating the plating section (14) from the processing section (12), and at least one opening defined in the partition wall (10) for transferring the substrate (W) between the plating section (14) and the processing section (12).

### TECHNICAL FIELD

The present invention relates to a plating apparatus, and more particularly to a plating apparatus for filling interconnection grooves formed in a semiconductor substrate with metal such as copper.

### BACKGROUND ART

Generally, aluminum or aluminum alloys have been used as a material for forming interconnection circuits on a semiconductor substrate. The higher integrated density of semiconductor devices requires that a material having a higher electric conductivity should be used for interconnection circuits. Therefore, there has been proposed a method which comprises plating a surface of a semiconductor substrate having trenches and/or holes defined therein for a circuit pattern to fill copper (Cu) or copper alloy into the trenches and/or holes, and removing the copper or copper alloy with the exception of the filled portion the surface to thus form interconnection circuits.

Heretofore, many plating apparatus for plating a surface of a semiconductor substrate comprise a robot disposed centrally for transferring a substrate, and identical processing units (e.g., plating units or cleaning units) disposed symmetrically on the left and right sides of the robot. In such plating apparatus, since the identical processing units are disposed symmetrically on the left and right sides of the robot, one side of the plating apparatus can individually be operated only when the plating apparatus can achieve a sufficient throughput.

Chemicals used in pre-processing and plating processes may be scattered as a chemical mist or gas into the facility and applied to the substrate which has been processed, for thereby causing contamination of the substrate. In order to prevent such contamination, it is necessary to enclose the processing units on both sides of the central robot for thereby preventing the chemical mist or gas from being scattered into the facility. Therefore, a large amount of air is required to be supplied to and discharged from a large contaminated space which surrounds the processing units on both sides of the central robot.

The plating units require a relay tank and a pressure pump for delivering a plating solution under pressure to a circulation tank. Since the plating units are disposed one on each side of the robot, relay tanks and pressure pumps are required for each of the left and right plating units.

### DISCLOSURE OF INVENTION

The present invention has been made in view of the above drawbacks. It is therefore an object of the present invention to provide a plating apparatus which can reduce a contaminated space in size and hence the amount of air required for supplying to and discharging from the contaminated space for thereby increasing contamination controllability, and can simplify a relay tank and a pressure pump required for a plating unit for thereby making the apparatus compact.

In order to achieve the above object, according to a first aspect of the present invention, there is provided a plating apparatus for plating a substrate, comprising: a loading/unloading section having a loading/unloading unit for loading and unloading substrates, and a first substrate transfer device for transferring the substrate from the loading/unloading unit; a processing section having at least one processing unit for processing the substrate, a plating section having at least one plating unit for plating the substrate, and a second substrate transfer device for transferring the substrate to the plating unit; a first air supplying system for supplying air into the processing section; and a second air supplying system for supplying air into the plating section independently of the first air supplying system.

According to a second aspect of the present invention, there is provided a plating apparatus for plating a substrate, comprising: a processing section having a loading/unloading unit for loading and unloading substrates, at least one processing unit for processing the substrate, a plating section having at least one plating unit for plating the substrate, and a substrate transfer device for transferring the substrate from the loading/unloading unit to the plating unit; a first air supplying system for supplying air into the processing section; and a second air supplying system for supplying air into the plating section independently of the first air supplying system.

With the above arrangement, the plating section (plating space) which is a contaminated space can be reduced in size, and hence it is possible to reduce the amount of air required for supplying to and discharging from the plating section. Therefore, the apparatus can be made compact, and the running cost can be reduced. Further, a relay tank and a pressure pump required for the plurality of plating unit can be simplified. Therefore, the apparatus can be made compacts and cost of equipment can be reduced.

According to a preferred aspect of the present invention, the processing unit comprises a substrate holder for holding the substrate.

According to a preferred aspect of the present invention, the plating unit comprises a plating container for holding a plating solution therein.

According to a preferred aspect of the present invention, the plating apparatus further comprises an air discharging system for discharging the air from the plating section. Preferably, the air discharging system discharges the air from the plating section so that the pressure in the plating section is lower than that in the processing section.

According to a preferred aspect of the present invention, the first air supplying system has a fan for supplying air into the processing section, and a circulation pipe for circulating the air in the processing section.

According to a preferred aspect of the present invention, the second air supplying system has a fan for supplying air into the plating section, and a circulation pipe for circulating the air in the plating section.

Preferably, the second transfer device according to the first aspect of the present invention transfers the substrate between the first substrate transfer device, the processing unit, and the plating unit. Preferably, the transfer device according to the second aspect of the present invention further transfers the substrate to the processing unit.

According to a preferred aspect of the present invention, the plating section is enclosed by a partition wall provided in the processing section; and at least one opening is defined in the partition wall to introduce the substrate into the plating section. Preferably, the substrate transfer device comprises a mobile-type robot. It is desirable that the substrate transfer device moves the substrate within the plating section, and no substrate transfer device is disposed within the plating section.

According to a preferred aspect of the present invention, the plating section has a plurality of plating units disposed adjacent to each other on one side of the substrate transfer device.

According to a preferred aspect of the present invention, the processing unit comprises an annealing unit for heating the substrate. Preferably, the annealing unit and the plating unit are disposed with the substrate transfer device being interposed therebetween.

According to a preferred aspect of the present invention, the processing unit comprises a cleaning unit for cleaning a peripheral portion of the substrate. Preferably, the cleaning unit and the plating unit are disposed with the substrate transfer device being interposed therebetween.

The above and other objects, features, and advantages of the present invention will be apparent from the following description when taken in conjunction with the accompanying drawings which illustrates preferred embodiments of the present invention by way of example.

### BRIEF DESCRIPTION OF DRAWINGS

FIGS. 1A through 1C are schematic views showing an example of a process for forming an interconnection in a semiconductor substrate;

FIG. 2 is a plan view showing an overall arrangement of a plating apparatus according to a first embodiment of the present invention;

FIG. 3 is an explanatory view showing flows of air in the plating apparatus shown in FIG. 2;

FIG. 4 is an enlarged cross-sectional view showing a main part of a plating unit shown in FIG. 2;

FIG. 5 is a plane view showing a plating process container shown in FIG. 4;

FIG. 6 is a schematic diagram showing a flow of a plating solution in the plating apparatus shown in FIG. 2;

FIG. 7 is a partial enlarged view showing a head shown in FIG. 4;

FIG. 8 is a schematic view showing a state in which a seed layer and a barrier layer have remained in a bevel portion as a result of CMP performed without bevel etching process of a semiconductor substrate;

FIG. 9 is a vertical cross-sectional view schematically showing a bevel and backside cleaning unit shown in FIG. 2;

FIG. 10 is a side view schematically showing a rotatable holding mechanism according to an embodiment of the present invention;

FIG. 11 is a plane view of FIG. 10;

FIG. 12 is a partial side view showing the details of a holding member in the rotatable holding mechanism shown in FIG. 10;

FIG. 13 is a partial bottom view as viewed in a direction shown by a line XIII-XIII of FIG. 12;

FIG. 14 is a schematic plan view showing an annealing unit shown in FIG. 2;

FIG. 15 is a vertical cross-sectional view of FIG. 14;

FIG. 16 is a cross-sectional view schematically showing a plating unit in a plating apparatus according to another embodiment of the present invention;

FIG. 17 is a cross-sectional view schematically showing a plating unit in a plating apparatus according to another embodiment of the present invention;

FIG. 18 is a cross-sectional view schematically showing a plating unit in a plating apparatus according to another embodiment of the present invention;

FIG. 19 is a cross-sectional view schematically showing a plating unit in a plating apparatus according to another embodiment of the present invention;

FIG. 20 is a cross-sectional view schematically showing a plating unit in a plating apparatus according to another embodiment of the present invention;

FIG. 21 is a cross-sectional view showing a whole structure of a plating unit at the time of plating process in a plating apparatus according to another embodiment of the present invention;

FIG. 22 is a cross-sectional view showing a whole structure of the plating unit shown in FIG. 21 at the time of non-plating process (at the time of transfer of a substrate);

FIG. 23 is a cross-sectional view showing a whole structure of the plating unit shown in FIG. 21 at the time of maintenance;

FIGS. 24A through 24D are schematic views explanatory of a flow of a plating solution of the plating unit shown in FIG. 21 at the time of plating process and at the time of non-plating process;

FIG. 25 is a partial enlarged view showing the plating unit shown in FIG. 21;

FIG. 26 is a cross-sectional view explanatory of a relationship among a housing, a pressing ring, and a substrate at the time of transfer of a substrate in the plating unit shown in FIG. 21;

FIG. 27 is an enlarged cross-sectional view showing a centering mechanism in the plating unit shown in FIG. 21;

FIG. 28 is a cross-sectional view showing a feeding contact (probe) in the plating unit shown in FIG. 21;

FIG. 29 is a plan view showing an overall arrangement of a plating apparatus according to another embodiment of the present invention;

FIG. 30 is a plan view showing an overall arrangement of a plating apparatus according to another embodiment of the present invention;

FIG. 31 is a plan view of an example of a substrate plating apparatus;

FIG. 32 is a schematic view showing airflow in the substrate plating apparatus shown in FIG. 31;

FIG. 33 is a cross-sectional view showing airflows among areas in the substrate plating apparatus shown in FIG. 31;

FIG. 34 is a perspective view of the substrate plating apparatus shown in FIG. 31, which is placed in a clean room;

FIG. 35 is a plan view of another example of a substrate plating apparatus;

FIG. 36 is a plan view of still another example of a substrate plating apparatus;

FIG. 37 is a plan view of still another example of a substrate plating apparatus;

FIG. 38 is a view showing a plan constitution example of the semiconductor substrate processing apparatus;

FIG. 39 is a view showing another plan constitution example of the semiconductor substrate processing apparatus;

FIG. 40 is a view showing still another plan constitution example of the semiconductor substrate processing apparatus;

FIG. 41 is a view showing still another plan constitution example of the semiconductor substrate processing apparatus;

FIG. 42 is a view showing still another plan constitution example of the semiconductor substrate processing apparatus;

FIG. 43 is a view showing still another plan constitution example of the semiconductor substrate processing apparatus;

FIG. 44 is a view showing a flow of the respective steps in the semiconductor substrate processing apparatus illustrated in FIG. 43;

FIG. 45 is a view showing a schematic constitution example of a bevel and backside cleaning unit;

FIG. 46 is a view showing a schematic constitution of an example of an electroless plating apparatus;

FIG. 47 is a view showing a schematic constitution of another example of an electroless plating apparatus;

FIG. 48 is a vertical sectional view of an example of an annealing unit;

FIG. 49 is a transverse sectional view of the annealing unit; and

FIG. 50 is a plan view showing an overall arrangement of a plating apparatus according to another embodiment of the present invention.

### BEST MODE FOR CARRYING OUT THE INVENTION

A plating apparatus according to embodiments of the present invention will be described below with reference to the accompanying drawings.

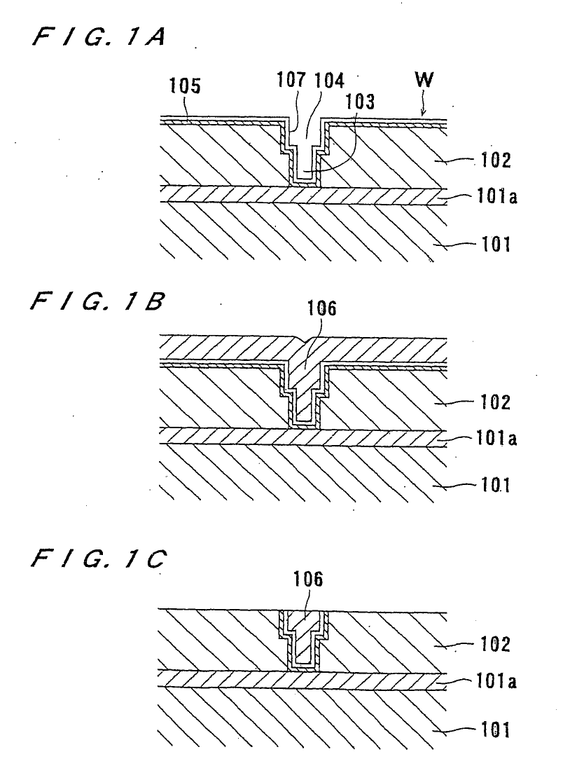

FIGS. 1A through 1C show an example of a process for electroplating a surface of a semiconductor substrate with copper to form a copper interconnection on the semiconductor substrate for thereby producing a semiconductor device with a plating apparatus according to an embodiment of the present invention.

As shown in FIG. 1A, a conductive layer 101a is formed on a semiconductor substrate 101 on which semiconductor devices have been formed, and an insulating film 102 of SiO₂ is deposited on the conductive layer 101a. A contact hole 103 and an interconnection groove 104 are formed in the insulating film 102 by lithography etching technology. Then, a barrier layer 105 made of TiN or the like is formed on the insulating film 102, and a seed layer 107, which is used as a feeding layer in an electrolytic plating, is further formed on the barrier layer 105.

Subsequently, as shown in FIG. 1B, the surface of the substrate W is plated with copper to fill the contact hole 103 and the interconnection groove 104 with copper and to deposit a copper film 106 on the insulating film 102. Thereafter, the surface of the substrate is polished to remove the copper film 106 from the insulating film 102 by chemical mechanical polishing (CMP) so that the surface of the copper film 106 filled in the contact hole 103 and the interconnection groove 104 is made substantially even with the surface of the insulating film 102. Thus, as shown in FIG. 1c, an interconnection comprising the copper film 106 is formed.

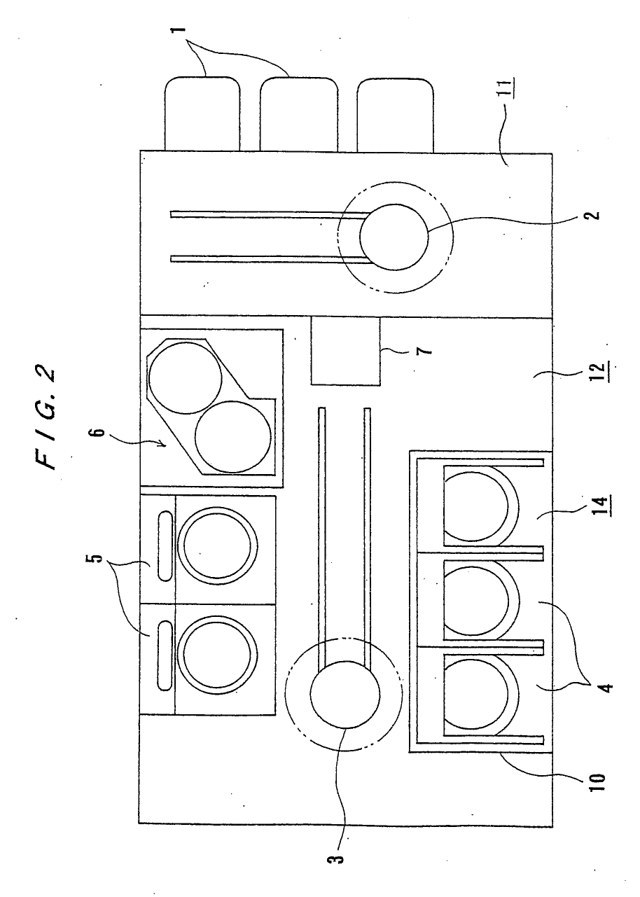

FIG. 2 is a plan view showing an overall arrangement of a plating apparatus according to a first embodiment of the present invention. As shown in FIG. 2, the plating apparatus is disposed in a clean room, and comprises a loading/unloading section 11 and a processing section (processing space) 12. The loading/unloading section 11 has three loading/unloading units 1 for placing substrate storage cassettes therein and for load and unload substrates in the cassettes, and a first mobile-type rotatable robot (substrate transfer device) 2 for transferring a semiconductor substrate from the loading/unloading units 1.

The substrate storage cassette may comprise a SMIF (standard mechanical interface) pod and a FOUP (front opening unified pod), which are sealed containers that permit lesser degree of cleanliness in the exterior environment of the pod. The processing section 12 has a second mobile-type rotatable robot (substrate transfer device) 3 for transferring a semiconductor substrate, three plating units 4 for plating a surface of the substrate with copper in such a state that the surface of the substrate faces downwardly, two bevel and backside cleaning units 5 for removing an unwanted copper film (seed layer) from the peripheral portion of the substrate, and an annealing unit 6 for stabilizing interconnections formed on the substrate.

A temporary holding stage 7 for placing and holding a substrate thereon is disposed between the first robot 2 and the second robot 3. The first robot 2 transfers a substrate between the cassettes placed on the loading/unloading units 1 and the temporary holding stage 7, and the second robot 3 transfers a substrate between the temporary holding stage 7, the plating units 4, the bevel and backside cleaning units 5, and the annealing unit 6.

The three plating units 4 are disposed adjacent to each other on one side of the second robot 3. A partition wall 10 is provided in the processing section 12 of the plating apparatus to define a plating section (plating space) 14 therein. Specifically, the plating section 14 is enclosed by the partition wall 10. The plating units 4 disposed adjacent to each other are surrounded by the plating section 14. The partition wall 10 has at least one opening (not shown) defined therein to introduce substrates therethrough from the processing section 12 into the plating section 14 and to discharge the substrates therethrough from the plating section 14 to the processing section 12. A shutter is provided on the partition wall 10 so as to open and close the opening. The second robot 3 moves the substrate with the plating section 14, and no robot for transferring a substrate is disposed in the plating section 14. As shown in FIG. 2, the bevel and backside cleaning units 5 and the plating units 4 are disposed with the second robot 3 being interposed therebetween, and the annealing unit 6 and the plating units 4 are disposed with the second robot 3 being interposed therebetween.

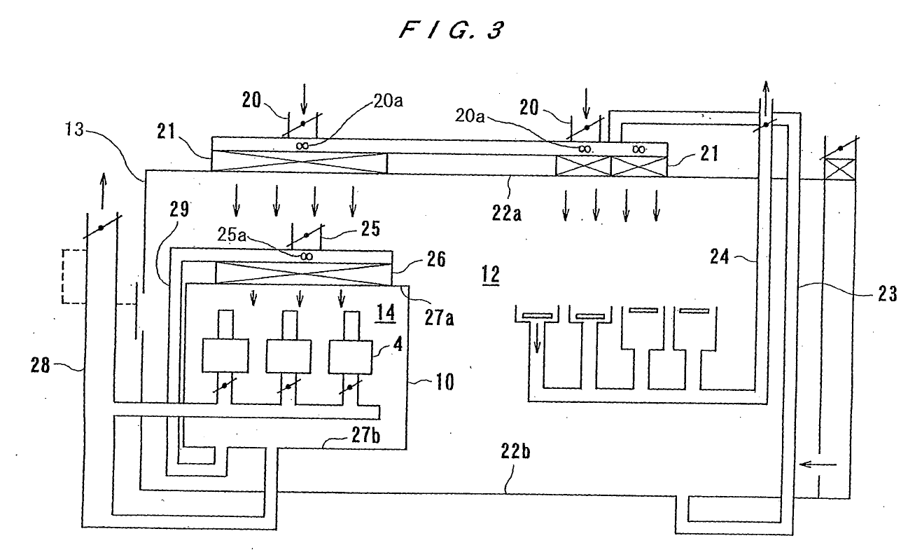

FIG. 3 shows flows of air in the plating apparatus. As shown in FIG. 3, the plating apparatus has a housing 13 to define the processing section 12 therein, and the plating section 14 is disposed within the processing section 12. Air can be supplied to and discharged from the plating section 14 independently of the processing section 12 outside of the plating section 14.

In the present embodiment, the plating apparatus comprises a first air supplying system for supplying air into the processing section 12, and a second air supplying system for supplying air into the plating section 14 independently of the first air supplying system. The first air supplying system has pipes 20 for introducing fresh external air into the processing section 12, fans 20a for supplying the fresh air into the processing section 12, high-performance filters 21, and a circulation pipe 23 for circulating the air in the processing section 12. The second air supplying system has a pipe 25 for introducing fresh external air into the plating section 14, a fan 25a for supplying the fresh air into the plating section 14, a high-performance filter 26, and a circulation pipe 29 for circulating the air in the plating section 14. The plating apparatus further comprises an air discharging system for discharging the air from the plating section 14. The air discharging system has a pipe 28 for discharging air from the plating section 14.

As shown in FIG. 3, fresh external air is introduced through the pipes 20 and pushed into the processing section 12 through the high-performance filters 21 by the fans 20a. Hence, the external air is supplied as downflow clean air from a ceiling 22a to positions around the units. A large part of the supplied clean air is returned from a floor 22b through the circulation pipe 23 to the ceiling 22a, and pushed again into the processing section 12 through the high-performance filters 21 by the fans 20a, so that the air is circulated in the processing section 12. A part of the air is discharged from the units through the pipe 24 to the exterior, so that the pressure of the processing section 12 is set to be lower than the atmospheric pressure.

The plating section 14 having the plating units 4 therein is not a clean space (but a contaminated space). However, it is not acceptable to attach particles to the surface of the substrate. Therefore, fresh external air is introduced as downflow clean air through the pipe 25 and pushed into the plating section 14 through the high-performance filter 26 by the fan 25a, for thereby preventing particles from being attached to the surface of the substrate. However, if the whole flow rate of the downflow clean air is supplied by only an external air supply and exhaust, then enormous air supply and exhaust are required. Therefore, the air is discharged through the pipe 28 to the exterior, and a large part of the downflow is supplied by circulating air through the circulation pipe 29 extended from a floor 27b, in such a state that the pressure of the plating section 14 is maintained to be lower than the pressure of the processing section 12. Thus, the air returned to a ceiling 27a through the circulation pipe 29 is pushed again into the plating section 14 through the high-performance filter 26 by the fan 25a. Hence, clean air is supplied into the plating section 14, so that the air is circulated in the plating section 14. In this case, air containing chemical mist or gas emitted from the plating units 4 is discharged through the pipe 28 to the exterior. Thus, the pressure of the plating section 14 is controlled so as to be lower than the pressure of the processing section 12.

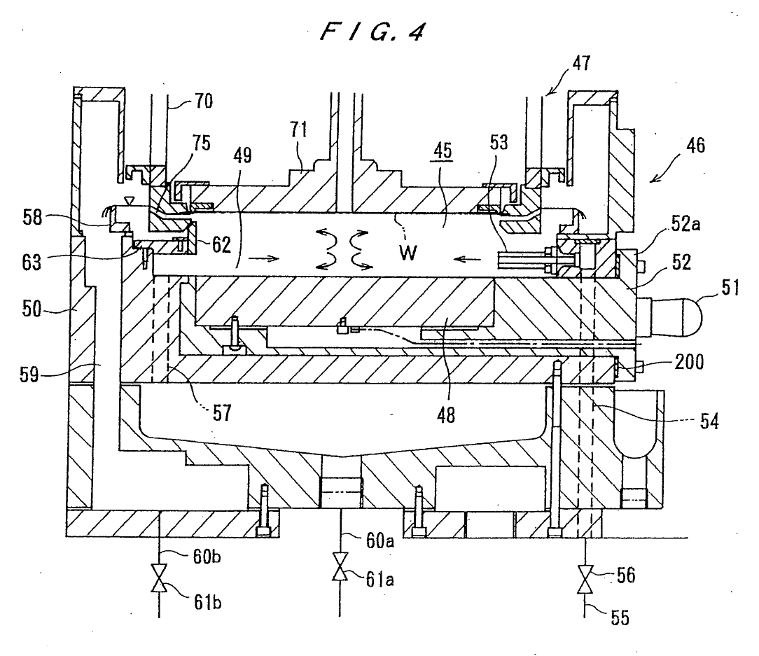

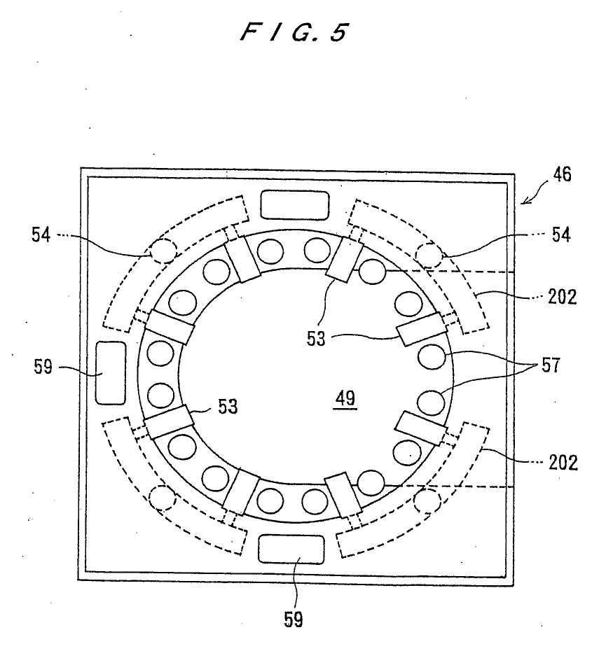

The plating unit 4 shown in FIG. 2 will be described below. FIG. 4 is an enlarged cross-sectional view showing a main part of the plating unit 4. As shown in FIG. 4, the plating unit 4 mainly comprises a plating process container 46 in a substantially cylindrical form for holding a plating solution 45 therein, and a head 47 disposed above the plating process container 46 for holding a substrate. In FIG. 4, the head 47 is located at a plating position in which a substrate W held by the head 47 is lowered.

The plating process container 46 is provided with a plating container 50 having a plating chamber 49, which is upwardly opened, for holding a plating solution therein. An anode 48 made of residual-phosphorus copper, for example, is provided at the bottom of the plating chamber 49. The anode 48 is connected to an anode of a power supply provided in an external control unit. The anode 48 is made of copper containing 0.03% to 0.05% phosphorus (residual-phosphorus copper), and hence a black film is formed on the upper surface of the anode 48 as plating proceeds. Such a black film can reduce generation of anode slime.

The anode 48 is held by an anode support 52, which is detachably mounted on the plating container 50, i.e., which is capable of being drawn via a knob 51 provided on the anode support 52. A sealing member 200 for preventing the plating solution from being leaked is interposed between the front surface of the plating container 50 and the backside surface of a flange 52a of the anode support 52. Thus, the anode 48 is held by the anode support 52 detachably mounted on the plating container 50, thereby allowing the anode 48 to be easily attached to and detached from the plating container 50 via the anode support 52. Accordingly, this construction facilitates maintenance and replacement of the anode 48 and the like.

FIG. 5 is a plan view showing the plating process container 46 shown in FIG. 4. As shown in FIGS. 4 and 5, plating solution supply nozzles 53 horizontally projecting toward the center of the plating chamber 49 are provided on the inner circumferential wall of the plating container 50 at equal intervals along the circumferential direction. Each of the plating solution supply nozzles 53 is communicated with a plating solution supply passage 54 extending vertically through the interior of the plating container 50. In the present embodiment, four circumferentially divided plating solution reservoirs 202 in an arc-shaped form are provided in the inner circumferential wall of the plating container 50. Each of the plating solution reservoirs 202 is communicated with the plating solution supply passage 54 located at the central portion along the circumferential direction of the plating solution reservoir 202. Each of the plating solution reservoirs 202 has the two plating solution supply nozzles 53 provided on both ends along the circumferential direction of the plating solution reservoir 202.

Further, the plating container 50 is provided with first plating solution discharge ports 57 for withdrawing the plating solution 45 in the plating chamber 49 from the peripheral portion of the bottom of the plating chamber 49, and second plating solution discharge ports 59 for discharging the plating solution 45 overflowing a weir member 58 provided at the upper end of the plating container 50. The first plating solution discharge ports 57 (16 ports in FIG. 5), which are in a circular form having a diameter of 16 mm to 20 mm, for example, are disposed at equal intervals along the circumferential direction. The second plating solution discharge ports 59 (3 ports in FIG. 5) are in an arc-shaped form having a central angle of about 25°.

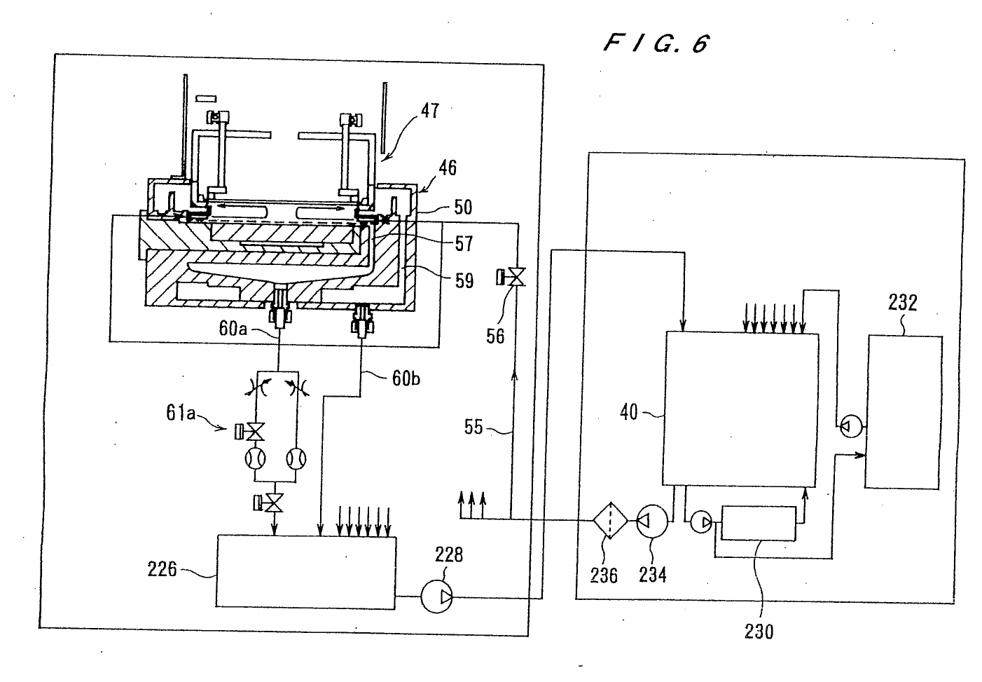

FIG. 6 is a schematic diagram showing the flow of the plating solution in the plating apparatus according to the present embodiment. Each of the plating solution supply passages 54 is connected to a plating solution regulating tank 40 via a plating solution supply pipe 55. Control valves 56 for controlling the back pressure so as to be constant are disposed on each of the plating solution supply pipes 55. The plating solution of the same flow rate is respectively supplied to each of the plating solution reservoirs 202 via the control valves 56. Therefore, the plating solution is homogeneously ejected from each of the plating solution supply nozzles 53 into the plating chamber 49.

Each of the first plating solution discharge ports 57 is connected to a reservoir 226 via a plating solution discharge pipe 60a. A flow controller 61a is provided on the plating solution discharge pipe 60a. On the other hand, each of the second plating solution discharge ports 59 is connected to the reservoir 226 via a plating solution discharge pipe 60b. A flow controller 61b (not shown in FIG. 6) is provided on the plating solution discharge pipe 60b. The flow controller 61b may not be provided.

The plating solution 45 ejected from the plating solution supply nozzles 53 is discharged to the reservoir 226 from one or both of the first plating solution discharge ports 57 and the second liquid discharge ports 59, for thereby keeping the liquid level of the plating solution in the plating chamber 49 at a constant value. The plating solution fed into the reservoir 226 is supplied to the plating solution regulating tank 40 from the reservoir 226 by a pump 228. In the plating solution regulating tank 40, the temperature of the plating solution is adjusted, and the concentration of various components in the plating solution is measured and adjusted. When a pump 234 is operated, the plating solution is supplied from the plating solution regulating tank 40 through a filter 236 to the plating solution supply nozzles 53 in each of the plating units 4. This plating solution regulating tank 40 is provided with a temperature controller 230 and a plating solution analyzing unit 232 for sampling the plating solution and analyzing the sample liquid.

A vertical stream regulating ring 62 and a horizontal stream regulating ring 63 are disposed within the plating chamber 49 at a position near the internal circumference of the plating chamber 49. The vertical stream regulating ring 62 serves to prevent the plating solution 45 from flowing horizontally outwardly in the plating chamber 49. The horizontal stream regulating ring 63 is fixed to the plating container 50 at the outer circumferential end thereof. The vertical stream regulating ring 62 is connected to the inner circumferential end of the horizontal stream regulating ring 63.

The plating solution horizontally ejected from each of the plating solution supply nozzles 53 collides with each other at the central portion of the plating chamber 49 to form an upward flow and a downward flow. When no substrate is held by the head 47, the upward flow pushes up the liquid surface of the plating solution 45 at the central portion inside the vertical stream regulating ring 62. When the substrate is lowered, the substrate is firstly brought into contact with the plating solution 45 at the central portion pushed up by the upward flow, and hence air bubbles on the lower surface of the substrate are pushed outwardly. On the other hand, the downward flow is changed to a horizontal flow flowing from the central portion of the anode 48 to the peripheral portion of the anode 48 to push away peeled fine pieces of a black film formed on the surface of the anode 48. The peeled pieces of the black film is passed from the peripheral portion of the anode 48 through the lower portion of the horizontal stream regulating ring 63 to the first plating solution discharge ports 57, so that the peeled pieces of the black film can be prevented from approaching and being attached to the surface of the substrate to be processed.

In the electroplating, the current density in the plating solution governs the thickness of the plated film. Therefore, in order to uniform the thickness of the plated film, it is necessary to uniform the distribution of the current density in the plating solution. When the peripheral portion of the substrate has electrical contacts, the current density of the plating solution present on the peripheral portion of the substrate tends to be increased. Therefore, the vertical stream regulating ring 62 extending vertically is disposed in the vicinity of the peripheral portion of the substrate, and the horizontal stream regulating ring 63 extending horizontally outwardly is disposed below the vertical stream regulating ring 62, for thereby regulating the electric current flowing in the vicinity of the peripheral portion of the substrate. Thus, these stream regulating rings can reduce local concentration of the electric current and can uniform the current density of the plating solution to thus prevent the plated film from being thick at the peripheral portion of the substrate. In the present embodiment, the vertical stream regulating ring and the horizontal stream regulating ring are used for regulating the electric current around the peripheral portion of the substrate. However, the present invention is not limited to this example.

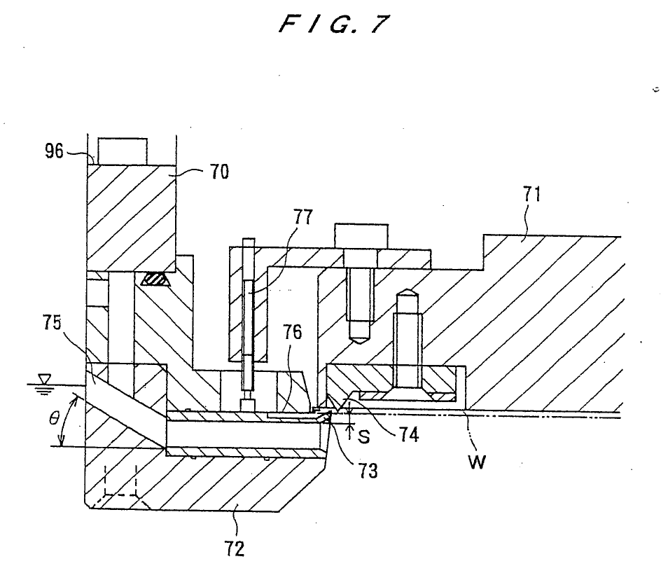

FIG. 7 is a partial enlarged view showing the head 47 of the plating unit 4. As shown in FIGS. 4 and 7, the head 47 of the plating unit 4 is provided with a rotatable housing 70 in a hollow cylindrical form and a disk-shaped substrate table 71 for holding a substrate W on its lower surface. The substrate table 71 is rotated together with the housing 70. A ring-shaped substrate holding member (substrate holder) 72 projecting radially inwardly is provided at the lower end of the housing 70. For example, the substrate holding member 72 is formed of a packing material and has a tapered surface on a part of its inner circumferential surface for guiding the substrate W. The peripheral portion of the substrate W is held between the substrate holding member 72 and the substrate table 71. The substrate table 71 is constituted as a pressing member for pressing the substrate W against the substrate holding member 72. Openings 96 are provided on both sides of the cylindrical surface of the housing 70 for allowing the substrate W and the robot hand to pass therethrough.

As shown in FIG. 7, a ring-shaped lower sealing member 73 is mounted on the substrate holding member 72. The lower sealing member 73 projects radially inwardly, and the front end of its upper surface projects upwardly in an annular tapered form. An upper sealing member 74 is mounted on the peripheral portion of the lower surface of the substrate table 71. The upper sealing member 74 has a spired portion projecting downwardly from the lower surface of the substrate table 71.

Thus, when the substrate W is held by the substrate holding member 72, the lower surface of the substrate W is brought into pressure contact with the lower sealing member 73, and the upper surface of the substrate W is brought into pressure contact with the upper sealing member 74, for thereby sealing the peripheral portion of the substrate W reliably.

In the present embodiment, eighty air vent holes 75 are formed in the substrate holding member 72 at equal intervals along the circumferential direction. Each of the air vent holes 75 extends horizontally outwardly and further extends outwardly in an upwardly inclined state. The air vent holes 75 are provided in such a state that, when the head 47 is located in the plating position, about half of the peripheral opening end of the air vent hole 75 is exposed to the exterior from the liquid surface of the plating solution 45 in the plating chamber 49. As described above, the upward flow of the plating solution 45 in the plating chamber 49 is brought into contact with the substrate W to sweep away air bubbles to the exterior from the central portion of the substrate W. Accordingly, the air bubbles swept by the upward flow are successively discharged to the exterior through the air vent holes 75. Thus, air bubbles can be prevented from remaining between the substrate W and the surface of the plating solution 45.

For example, the angle θ of inclination of the air vent holes 75 is set to be 30°. Further, the air vent holes 75 should preferably be inclined upwardly in the outward direction at an angle of not less than 20°, and more preferably about 30°.

When the venting of air is taken into consideration, the air vent holes 75 should preferably have a diameter of 2 mm to 5 mm, and more preferably about 3 mm. The air vent holes 75 may be branched into two holes, one of which is opened in the vicinity of the liquid surface, and the other of which is opened at a position fully above the liquid surface. Each of the air vent holes 75 may be provided in any form, e.g., in a linear form, or each of the air vent holes 75 may be branched outwardly into two holes. It has been confirmed that, when a gaps between the lower surface of the substrate W held on the lower surface of the substrate table 71 and the upper end of the air vent holes 75 is not more than about 1.5 mm, air can be vented in a short time.

As shown in FIG. 7, plate-spring-like contacts 76 for a cathode electrode are disposed on the substrate holding member 72 of the housing 70. When the substrate W is held on the lower surface of the substrate table 71, the contacts 76 for a cathode electrode energize the substrate W. Feeding contacts (probes) 77 are vertically downwardly provided at the outer circumferential side of the substrate table 71. When the substrate table 71 is lowered, each of the feeding contacts 77 feeds power to each of the contacts 76 for a cathode electrode. Since the plating solution 45 is sealed with a lower sealing member 73 disposed between the substrate W and the substrate holding member 72, the contacts 76 for a cathode electrode and the feeding contacts 77 can be prevented from being brought into contact with the plating solution 45.

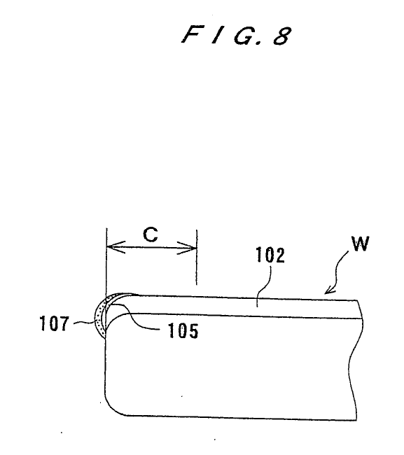

The bevel and backside cleaning unit 5 shown in FIG. 2 will be described below. In FIG. 1A, the barrier layer 105 is formed so as to cover a substantially entire surface of the insulating film 102, and the seed layer 107 is also formed so as to cover a substantially entire surface of the barrier layer 105. Thus, in some cases, as shown in FIG. 8, a copper film which is the seed layer 107 resides in a bevel (outer peripheral portion) of the substrate W, or copper is deposited on an edge (outer peripheral portion) inwardly of the bevel of the substrate W and remains unpolished (not shown in the drawings).

Copper can easily be diffused into the insulating film 102 in a semiconductor fabrication process such as annealing, for example, thus deteriorating the electric insulation of the insulating film and impairing the adhesiveness of the insulating film with a film to be subsequently deposited to cause separation of the deposited film. It is therefore necessary to remove the remaining unnecessary copper completely from the substrate at least before film deposition. Furthermore, copper deposited on the outer peripheral portion of the substrate other than the circuit formation area is not only unnecessary, but may cause cross contamination in subsequent processes of delivering, storing and processing the semiconductor substrate. For these reasons, it is necessary that the remaining deposited copper on the peripheral portion of the substrate should be completely removed immediately after the copper film deposition process or the CMP process. Here, the outer peripheral portion of the substrate is defined as an area including an edge and a bevel of the substrate W, or either the edge or the bevel. The edge of the substrate means areas of the front and reverse surfaces of the substrate W within about 5 mm from the outer peripheral end of the substrate, and the bevel of the substrate means an area of the outer peripheral end surface and a curved portion in cross section of the substrate W within 0.5 mm from the outer peripheral end of the substrate.

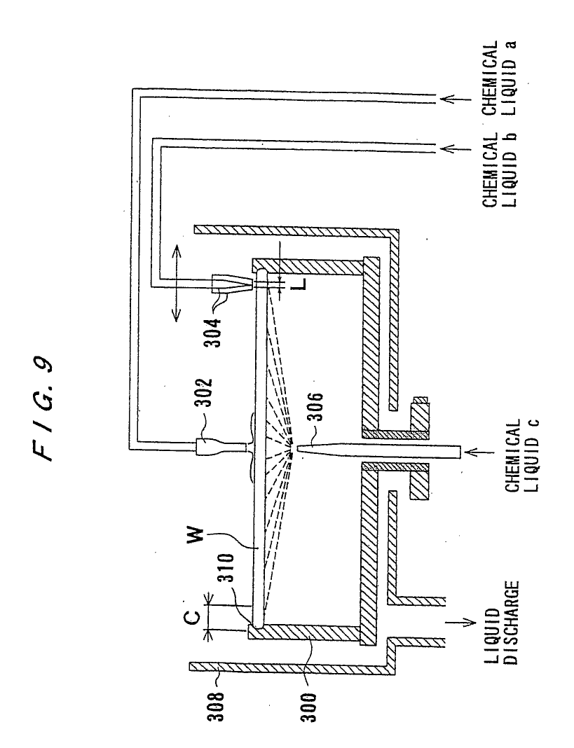

The bevel and backside cleaning unit 5 can perform an edge (bevel) Cu etching and a backside cleaning at the same time, and can suppress growth of a native oxide of copper at the circuit formation area on the surface of the substrate. FIG. 9 is a vertical cross-sectional view schematically showing the bevel and backside cleaning unit 5 shown in FIG. 2. As shown in FIG. 9, the bevel and backside cleaning unit 5 has a substrate holding portion (substrate holder) 300 adapted to rotate the substrate W horizontally at a high speed, a center nozzle 302 placed above a nearly central portion of the front surface of the substrate W held by the substrate holding portion 300, and an edge nozzle 304 placed above the peripheral edge portion of the substrate W.

The substrate holding portion 300 is positioned inside a bottomed cylindrical waterproof cover 308 and adapted to rotate a substrate W at a high speed, in such a state that the front surface of the substrate W faces upwardly, while holding the substrate W horizontally by rotatable holding mechanisms (spin chucks) 310 at a plurality of locations along a circumferential direction of a peripheral edge portion of the substrate. The center nozzle 302 and the edge nozzle 304 are directed downwardly. A back nozzle 306 is positioned below a nearly central portion of the backside of the substrate W, and directed upwardly.

The edge nozzle 304 is adapted to be movable in a diametrical direction and a height direction of the substrate W. The width of movement L of the edge nozzle 304 is set such that the edge nozzle 304 can be arbitrarily positioned in a direction toward the center from the outer peripheral end surface of the substrate, and a set value for L is inputted according to the size, usage, or the like of the substrate W. Normally, an edge cut width C is set in the range of 2 mm to 5 mm. In the case where the substrate is rotated at not less than a certain speed at which the amount of liquid migration from the backside to the face is not problematic, the copper film within the edge cut width C can be removed.

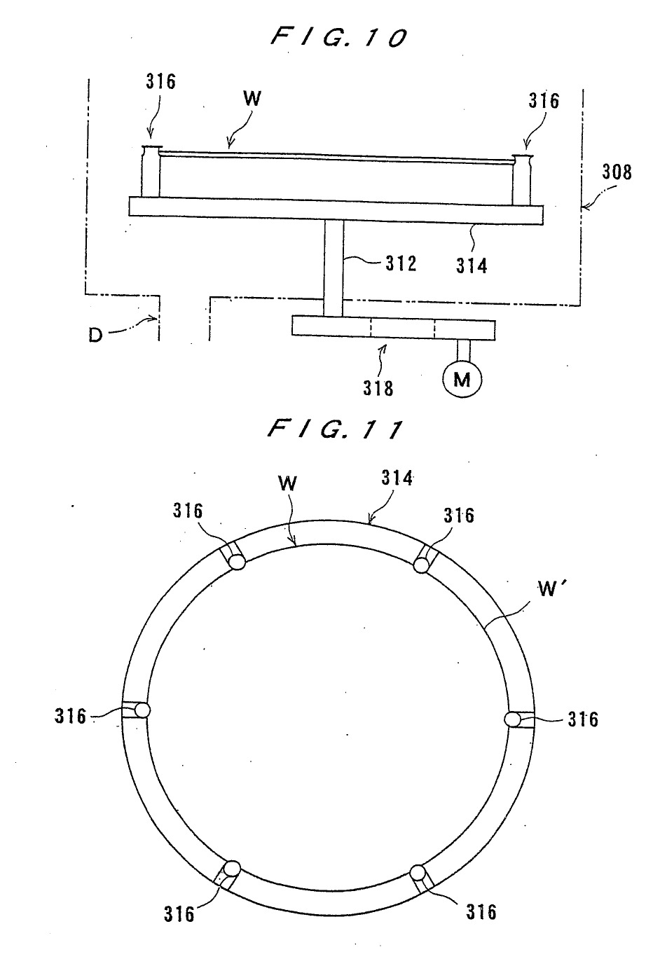

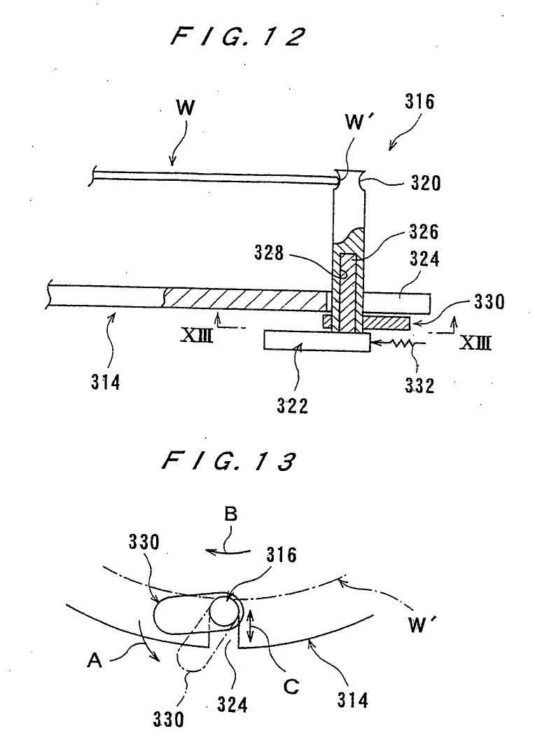

The rotatable holding mechanism 310 will be described below. FIG. 10 is a side view schematically showing the rotatable holding mechanism 310, and FIG. 11 is a plan view of FIG. 10. The rotatable holding mechanism 310 serves to rotate the substrate W while holding it horizontally. The rotatable holding mechanism 310 comprises a disk-shaped rotatable member 314 that is set horizontally and rotated by a rotatable drive shaft 312, and a plurality of holding members 316 for holding substrate W above the rotatable member 314. The holding members 316 are mounted on the peripheral portion of the rotatable member 314 and arranged along a circle with the rotatable drive shaft 312 as a center, with each two adjacent members being spaced at a predetermined distance (60° in the embodiment of FIG. 11). The holding members 316 engages the periphery W′ of the substrate W, thereby holding the substrate W horizontally.

The rotatable drive shaft 312 is coupled to a motor M via a belt driving device 318. The waterproof cover 308 serves to prevent a chemical liquid supplied from the center nozzle 302 and the edge nozzle 304 to the substrate W from scattering around the substrate W and to correct the scattered liquid, which is discharged through a discharge pipe D.

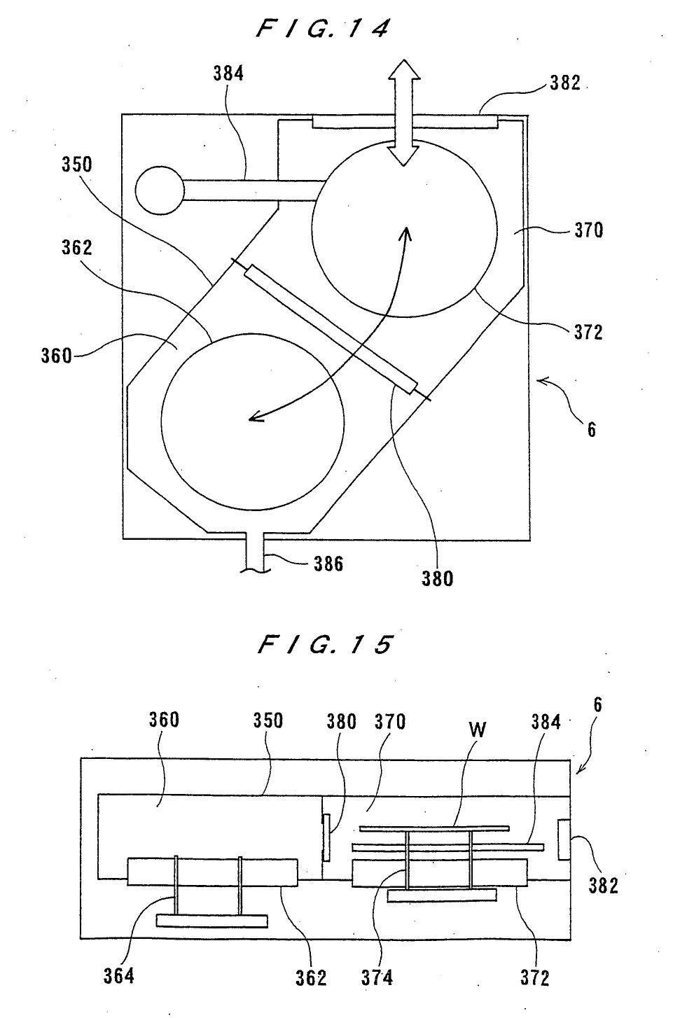

FIG. 12 is a partial side view showing the details of the holding member 316, and FIG. 13 is a partial bottom view as viewed in a direction shown by a line XIII-XIII of FIG. 12. As shown in FIG. 12, the holding member 316 is in a substantially columnar form, and has near its top an engaging surface 320 formed in an annular groove form. The engaging surface 320 is held in friction engagement with the periphery W′ of the substrate W. A holding plate 322 is disposed below the rotatable member 314 and rotated together with the rotatable member 314. As shown in FIG. 13, the holding member 316 vertically penetrates a slot 324 formed in the peripheral portion of the rotatable member 314 and extending in the radial direction of the rotatable member 314. The lower portion of the holding member 316 is held by the holding plate 322, and hence the holding member 316 is rotatable about the axis thereof. Specifically, the holding plate 322 has a small-diameter shaft 326 extending vertically upwardly, and the holding member 316 has a hole 328 defined therein and extending upwardly from the bottom of the holding member 316. The hole 328 is moveably fitted with the small-diameter shaft 326, so that the holding member 316 is rotatable about the small-diameter shaft 326.

Further, a weight 330 which extends horizontally is mounted on the lower end of the holding member 316. When the rotatable member 314 is rotated about its axis of rotation, i.e., the rotatable drive shaft 312, for thereby rotating (or revolving) the holding member 316 about the shaft 312, a centrifugal force is acted on the weight 330 to swivel (swing) the holding member 316 about its own axis. The position of the weight 330 shown by the solid line in FIG. 13 represents a home position at which the weight 330 is pressed by a resilient member (not shown). When a certain centrifugal force is acted on the weight 330, the weight 330 is moved in the direction of the arrow A towards a position shown by the chain line, so that the substrate W is rotated in the direction of the arrow B.

The holding plate 322 is supported by a link mechanism or the like (not shown) so as to be horizontally movable along the slot 324 in the direction of the arrow C, i.e., the radial direction of the rotatable member 314. Hence, the holding plate 322 is movable between an engaging/holding position (the position shown in FIG. 12) where the holding member 316 engages the periphery W′ of the substrate W and a release position spaced radially outwardly from the engaging/holding position. Further, the holding plate 322 is pressed radially inwardly of the rotatable member 314 by a spring 332 so that the engaging surface 320 of the holding member 316 in the engaging/holding position elastically engages the periphery W′ of the substrate W through the spring 332.

The operation of the rotatable holding mechanism 310 for holding and rotating the substrate W will be described. First, each of the holding members 316 is moved against the pressure of the spring 332 to the release position positioned radially outwardly of the rotatable member 314. Thereafter, the substrate W is set horizontally above the rotatable member 314, and the holding member 316 is returned to the engaging/holding position to bring the engaging surface 320 into engagement with the periphery W′ of the substrate W, thereby allowing the holding member 316 to elastically hold the substrate W.

When the rotatable member 314 is rotated to revolve the holding member 316, a centrifugal force is acted on the weight 330. When the rotational speed of the rotatable member 314 is low, the centrifugal force acting on the weight 330 is small and the weight 330 is kept motionless due to the pressure by the spring which presses the weight 330 towards the home position. When the rotational speed of the rotatable member 314 is higher than a particular value, the centrifugal force acting on the weight 330 exceeds the counter pressure of the spring and causes the weight 330 to swing, for thereby swinging (or rotating) the holding member 316 about its own axis. Since the holding member 316 is held in friction engagement with the periphery W′ of the substrate W as described above, the swinging of the holding member 316 makes the substrate W rotate in the direction of the arrow B shown in FIG. 13. Thus, the engaging portion to the periphery W′ of the substrate W is shifted according to the swinging of the holding member 316.

According to the embodiment shown in FIGS. 12 and 13, the weight 330 having a center of gravity at a position that is eccentric to the central axis of the holding member 316 is mounted on the holding member 316. The use of such an eccentric weight 330 enables the holding member 316 to swing (rotate) about its own axis according to the rotation of the rotatable member 314. However, the mechanism for swinging (rotating) the holding member 316 is not limited thereto. For example, a link mechanism may be connected to the holding member 316, and the holding member 316 may be allowed to swing (rotate) through the action of the link mechanism.

When the rotatable holding mechanism thus constructed is used to hold and rotate a substrate such as a semiconductor wafer, the peripheral portions of the substrate in engagement with the holding members can be shifted during the bevel etching (i.e., etching of the edge and the bevel of the substrate). Therefore, a chemical liquid used in the bevel etching can be supplied to the entire peripheral area of the substrate W, for thereby enabling a satisfactory cleaning treatment.

Although the rotatable holding mechanism 310 can be applied not only to the bevel and backside cleaning unit 5, but also to other cleaning devices, it is most suitable to employ the rotatable holding mechanism in the bevel and backside cleaning unit 5. With the use of the rotatable holding mechanism 310 in the bevel and backside cleaning unit 5, the substrate can reliably be held by the rotatable holding mechanism 310, and the edge portion (the periphery W′) of the substrate W in engagement with the holding member 316 can be shifted to etch the entire edge and bevel portion of the substrate W. Further, since a workpiece to be rotated, such as a semiconductor wafer, is held by all of the holding members that are provided in the rotatable holding mechanism, the workpiece to be rotated can reliably be held by the rotatable holding mechanism and hence particles are prevented from being generated.

The annealing unit 6 shown in FIG. 2 will be described below. FIG. 14 is a plan view schematically showing the annealing unit 6, and FIG. 15 is a vertical cross-sectional view of the annealing unit 6 shown in FIG. 14.

As shown in FIGS. 14 and 15, the annealing unit 6 has a heater 360 and a cooler 370 which are juxtaposed in one plane within a chamber 350. The heater 360 has a hot plate 362 for heating a substrate W to 400° C., for example, and the cooler 370 has a cool plate 372 for cooling a substrate W with a flow of cooling water.

The heater 360 has a plurality of vertically movable pins (substrate holders) 364 extending vertically through the hot plate 362 for supporting the substrate W on their upper ends. Similarly, the cooler 370 has a plurality of vertically movable pins (substrate holders) 374 extending vertically through the cool plate 372 for supporting the substrate W on their upper ends.

An openable and closable shutter 380 is positioned between the heater 360 and the cooler 370. An openable and closable gate 382 for transferring the substrate W into and out of the chamber 350 is disposed in the chamber 350 near the cooler 370. The chamber 350 also houses therein a transfer arm 384 for transferring the substrate W between the heater 360 and the cooler 370.

The hot plate 362 and the cool plate 372 have a plurality of purge holes (not shown) defined in outer circumferential regions thereof for introducing an antioxidant gas into the chamber 350. A mixture of N₂ and H₂ gases is introduced as the antioxidant gas from the purge holes through a filter (not shown) into the chamber 350. A gas discharge pipe 386 is connected to the chamber 350 for discharging the antioxidant gas which has been introduced from the purge holes into the chamber 350. In the present embodiment, a mixture of N₂ gas and a few percents of H₂ gas is introduced as the antioxidant gas. However, only an N₂ gas may be introduced as the antioxidant gas into the chamber 350.

Next, a series of plating processes using the plating apparatus according to the present embodiment will be described below.

As shown in FIG. 1A, a contact hole 103 and an interconnection groove 104 are formed in the semiconductor substrate, and a seed layer 107 is further formed thereon. A cassette housing a plurality of semiconductor substrates W is placed on a loading/unloading unit 1 in such a state that surfaces (surface on which semiconductor devices are formed, i.e., surface to be processed) face upwardly.

The first robot 2 moves to the loading/unloading unit 1 on which the cassette is placed, and then inserts its hand into the cassette. The first robot 2 takes up a substrate from the cassette, then moves to the temporary holding stage 7, and places the substrate on the temporary holding stage 7. The substrate placed on the temporary holding stage 7 is reversed by an inverter combined with the temporary holding stage 7 so that the surface of the substrate faces downwardly.

The second robot 3 moves to the temporary holding stage 7 and holds the substrate from below with its hand. The second robot 3 then moves to one of the plating units 4 and transfers the substrate to the head 47 of the plating unit 4 through the opening (not shown) in the partition wall 10. At this time, the housing 70 and the substrate table 71 of the plating unit 4 has been elevated to a substrate attaching/removing position, with the substrate table 71 being lifted to the upper end of the housing 70. The second robot 3 inserts its hand and the substrate into the housing 70 through the opening 96 defined therein, and lifts its hand up to a position beneath the substrate table 71. Then, hooks (not shown) are closed under the bias of a helical compression spring to hold the substrate. After the substrate is held by the hooks, the hand of the second robot 3 is slightly lowered and drawn out from the opening 96 in the housing 70.

In the plating unit 4, the substrate is plated to form a copper film 106 on the surface of the substrate. In the plating process, the substrate table 71 is lowered, and the substrate is centered by the tapered portion on the inner side of the substrate holding member 72 of the housing 70. The substrate is placed on the lower sealing member 73 of the substrate holding member 72, and further pressed against the upper sealing member 74 near the peripheral portion of the substrate table 71 to form a seal for preventing the plating solution from entering the electrode contact side. At the same time, the substrate table 71 is lowered to press the feeding contacts 77 against the contacts 76 for a cathode electrode, for thereby achieving reliable contacts.

In this state, when the plating solution is ejected through the plating solution supply nozzles 53 in the plating process container 46, the liquid surface is raised in its center portion. At the same time, the substrate W and the substrate table 71 are lowered by a ball screw or the like while being rotated at a medium speed of 150 min⁻¹, for example. The rotational speed of the substrate is preferably about 100 to 250 min⁻¹ from the viewpoint of the removal of air. In this case, after the central portion of the substrate is brought into contact with the surface of the plating solution 45, the area of contact between the substrate and the raised liquid surface increases gradually, and then the plating solution 45 reaches the periphery of the substrate. In the periphery of the lower surface of the substrate, the lower sealing member 73 projects from the substrate surface, and hence air is likely to be left on the periphery of the lower surface of the substrate. However, by allowing the plating solution containing air bubbles to flow to the exterior through the air vent holes 75 by the rotation of the housing 70, air bubbles can be removed from the lower surface of the substrate. Thus, air bubbles on the lower surface of the substrate can completely be removed, and uniform plating can be realized. The predetermined position where the substrate is plated is such that the substrate is immersed in the plating solution 45 within the plating chamber 49 and the plating solution does not enter the housing 70 through the openings 96.

When the substrate is lowered to a predetermined position, the housing 70 is rotated at a medium speed for several seconds to remove air. The rotational speed of the housing 70 is then lowered to a low rotational speed of 100 min⁻¹, for example, and a plating current is flowed for electroplating the substrate in such a state that the anode 48 serves as an anode and the surface, to be processed, of the substrate serves as a cathode. In this case, the rotational speed is in the range of 0 to 225 min⁻¹, for example. During the plating process, the plating solution is continuously supplied at a predetermined flow rate through the plating solution supply nozzles 53 and discharged through the first plating solution discharge ports 57 and the second plating solution discharge ports 59. The plating solution is circulated through the plating solution regulating tank 40. In this case, since the plating thickness is determined by the current density and the current feed time, the current feed time (plating time) is set according to a desired amount of deposition.

After the completion of the feed of current, the housing 70, the substrate W, and the substrate table 71 is lifted to a position above the surface of the plating solution 45 within the plating-chamber 49 and below an upper end of a plating process container cover. Then, the substrate is rotated at a high speed of 500 to 800 min⁻¹, for example, to remove the plating solution from the substrate under a centrifugal force. After the completion of the removal of the liquid from the substrate, the rotation of the housing 70 is stopped so that the housing 70 faces in a predetermined direction. After the housing 70 is lifted to the substrate attaching/removing position, the substrate table 71 is further lifted to the substrate attaching/removing position.

Next, the hand of the second robot 3 is inserted into the housing 70 through the opening 96 of the housing 70 and is lifted to a position where the hand receives the substrate. Then, the hooks (not shown) are opened to drop the substrate held by the hooks onto the recess-type hand. In this state, the hand is slightly lowered, and the hand and the substrate held by the hand are taken out through the opening 96 of the housing 70. The substrate is held in such a manner that the surface of the substrate faces downwardly and only the peripheral edge of the substrate is brought into contact with the hand, as with mounting the substrate with the hand.

The second robot 3 takes out the substrate W from the plating unit 4, and the substrate W held by the second robot 3 is transferred to the bevel and backside cleaning unit 5 where an unnecessary Cu film (seed layer) is removed from a peripheral portion of the semiconductor substrate. In the bevel and backside cleaning unit 5, the bevel is etched in a preset time, and Cu adhering to the backside of the semiconductor substrate is cleaned with a chemical liquid such as hydrofluoric acid. The region etched by bevel etching is a region which corresponds to a peripheral edge portion of the substrate and has no circuit formed therein, or a region which is not utilized finally as a chip although a circuit is formed. A bevel portion is included in this region.

Next, the method of cleaning in the bevel and backside cleaning unit 5 will be described. First, the semiconductor substrate W is horizontally rotated integrally with the substrate holding portion 300, with the substrate being held horizontally by the rotatable holding mechanisms 310 of the substrate holding portion 300. In this state, an acid solution is supplied from the center nozzle 302 to the central portion of the surface of the substrate W. The acid solution may be a non-oxidizing acid such as hydrofluoric acid, hydrochloric acid, sulfuric acid, citric acid, oxalic acid, or the like. On the other hand, an oxidizing agent solution is supplied continuously or intermittently from the edge nozzle 304 to the peripheral edge portion of the substrate W. One of an aqueous solution of ozone, an aqueous solution of hydrogen peroxide, an aqueous solution of nitric acid, and an aqueous solution of sodium hypochlorite, or a combination thereof is used as the oxidizing agent solution.

In this manner, the copper film or the like formed on the upper surface and end surface in the region of the peripheral edge portion C of the semiconductor substrate W is rapidly oxidized with the oxidizing agent solution, and is simultaneously etched with the acid solution supplied from the center nozzle 302 and spread on the entire surface of the substrate, so that the copper film or the like is dissolved and removed. By mixing the acid solution and the oxidizing agent solution at the peripheral edge portion of the substrate, a steeper etching profile can be obtained, in comparison with the case a mixture of them which has been prepared in advance is supplied to the surface of the substrate. At this time, the copper etching rate is determined by their concentrations. If a native oxide of copper is formed in the circuit formation area on the surface of the substrate, then this native oxide is immediately removed by the acid solution spreading on the entire surface of the substrate according to rotation of the substrate, and does not grow any more. Specifically, the oxide film of copper, which has been formed on the surface of the substrate in the plating, can thus be removed by flowing HF over the surface of the substrate. Further, an oxide film of copper is not newly formed during the etching. It is noted in this connection that when an oxide film of copper remains on the surface of the substrate, only the oxide portion of copper is preferentially polished away in a later CMP processing, which adversely affects the flatness of the processed surface. This adverse effect can be avoided by the removal of the oxide film of copper in the above manner.

After the supply of the acid solution from the center nozzle 302 is stopped, the supply of the oxidizing agent solution from the edge nozzle 304 is stopped. As a result, silicon exposed on the surface is oxidized, and deposition of copper can be suppressed. Thus, the activated surface of Si exposed on the surface of the substrate, for example, can be oxidized and thereby inactivated by later stopping the supply of H₂O₂. This prevents adsorption of large particles onto the surface of the substrate which may cause scratching in a later CMP processing.

Thus, the repeated processes of the oxidation of copper by H₂O₂ and the removal of the oxidized copper by HF can enhance the rate of copper removal as compared with the case where the oxidation of copper and its removal are simultaneously performed by using a mixture of H₂O₂ and HF.

On the other hand, an oxidizing agent solution and a silicon oxide film etching agent are supplied simultaneously or alternately from the back nozzle 306 to the central portion of the backside of the substrate. As a result, copper or the like adhering in a metal form to the backside of the semiconductor substrate W can be oxidized with the oxidizing agent solution, together with silicon of the substrate, and can be etched and removed with the silicon oxide film etching agent. This oxidizing agent solution is preferably the same as the oxidizing agent solution supplied to the front surface, because the types of chemicals are decreased in number. Hydrofluoric acid can be used as the silicon oxide film etching agent. When hydrofluoric acid is also used as the acid solution on the surface of the substrate, the types of chemicals can be decreased in number. If the supply of the oxidizing agent is stopped first, then a hydrophobic surface is obtained. If the etching agent solution is stopped first, then a water-saturated surface (a hydrophilic surface) is obtained. Thus, the backside surface can be adjusted to a condition which will satisfy the requirements of a subsequent process.

In this manner, the acid solution, i.e., etching solution is supplied to the substrate to remove metal ions remaining on the surface of the substrate W. Then, pure water is supplied to replace the etching solution with pure water and remove the etching solution. Thereafter, the substrate is dried by spin-drying. In this manner, removal of the copper film in the edge cut width C at the peripheral edge portion on the surface of the semiconductor substrate, and removal of copper contaminants on the backside are performed simultaneously to thus allow this treatment to be completed within 80 seconds, for example. The etching cut width of the edge can be set arbitrarily (to 2 mm to 5 mm), but the time required for etching does not depend on the cut width.

Then, the second robot 3 transfers the substrate which has been processed in the bevel and backside cleaning unit 5 to the annealing unit 6 in order to stabilize interconnections formed on the substrate. In the annealing unit 6, the gate 382 is opened, and the hand of the second robot 3 is inserted into the chamber 350 and places the substrate W on the vertically movable pins 374 of the cooler 370. After the vertically movable pins 374 are lifted, the hand of the second robot 3 is drawn out from the gate 382. Thereafter, the gate 382 is closed, and the vertically movable pins 374 of the cooler 370 are lowered. The mixture of gases is introduced from the purge holes defined in the outer circumferential region of the cool plate 372 into the cooler 370 for replacing the nitrogen.

After the replacement of the nitrogen, the shutter 380 located between the heater 360 and the cooler 370 is opened, and the transfer arm 384 is lifted and rotated. The transfer arm 384 holds the substrate W on the cool plate 372 and transfer the substrate W to the heater 360. The semiconductor substrate W which has been transferred by the transfer arm 384 is placed on the vertically movable pins 364 of the heater 360. Then, the transfer arm 384 is withdrawn to the cooler 370, and the shutter 380 is closed. The vertically movable pins 364 are lowered to a position at which the distance between the semiconductor substrate W held on the vertically movable pins 364 and the hot plate 362 becomes 0.1-1.0 mm, for example. In this state, the semiconductor substrate W is heated to 400° C., for example, through the hot plate 362, and simultaneously the antioxidant gas is introduced from the purge holes defined in outer circumferential regions of the hot plate 362. The antioxidant gas flows between the semiconductor substrate W and the hot plate 362 and is discharged from the gas discharge pipe 386. As a result, the semiconductor substrate W is annealed with preventing its oxidation. The annealing process may be completed in about several tens of seconds to 60 seconds. The heating temperature of the substrate may be selected in the range of 100-600° C.

After the annealing, the vertically movable pins 364 are lifted, and the shutter 380 is opened to introduce the transfer arm 384 from the cooler 370 to the heater 360. Then, the vertically movable pins 364 are lowered so that the substrate W is held by the transfer arm 384. The substrate is transferred to the cooler 370 by transfer arm 384. The substrate W which has been transferred by the transfer arm 384 is placed on the vertically movable pins 374 of the cooler 370. Then, the shutter 380 is closed. The vertically movable pins 374 are lowered to a position at which the distance between the semiconductor substrate W held on the vertically movable pins 374 and the cool plate 372 becomes 0-0.5 mm, for example. In this state, the semiconductor substrate W is cooled to 100° C. or lower for 10-60 seconds, for example, through the cool plate 372 into which cooling water is introduced.

After the substrate is cooled, the vertically movable pins 374 are lifted, the gate 382 is opened, and the hand of the second robot 3 is inserted into the chamber 350. The hand of the second robot 3 holds the substrate W placed on the vertically movable pins 374, and removes the substrate W from the annealing unit 6. The substrate W removed from the annealing unit 6 is placed on the temporary holding stage 7 again, and then returned into the cassette in the loading/unloading unit 1 by the first robot 2.

While the present invention has been described in detail with reference to the preferred embodiments thereof, it would be apparent to those skilled in the art that many modifications and variations may be made therein without departing from the spirit and scope of the present invention. Other embodiments of the present invention will be described below. Like parts and components are designated by the same reference numerals as those shown in the above embodiment. Parts not particularly referred to in the following description are the same as parts in the above embodiment.

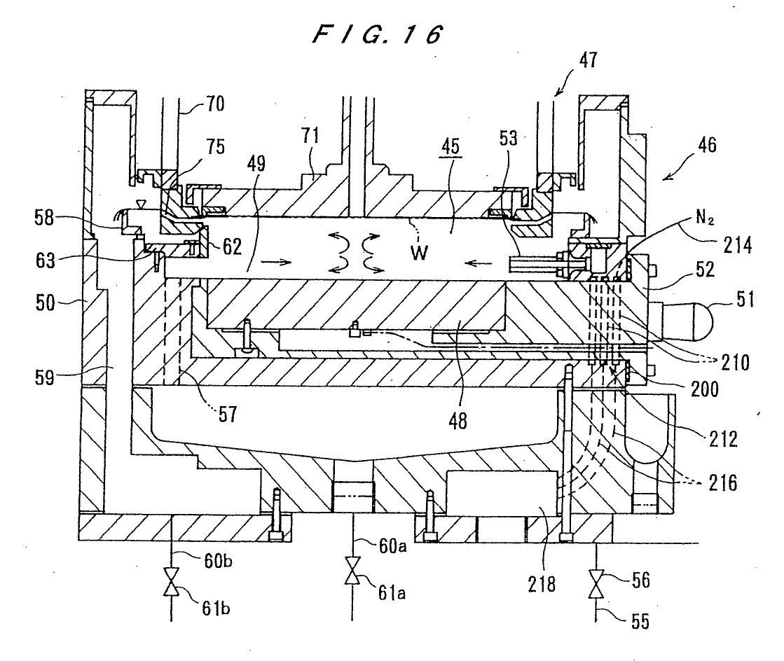

FIG. 16 is a vertical cross-sectional view schematically showing a plating unit according to another embodiment of the present invention. In this embodiment, a labyrinth seal 212 comprising a large number of grooves 210 arranged in parallel is provided around the inlet of the anode support 52 which holds the anode 48. An inert gas introduction passage 214 for introducing inert gas such as nitrogen gas is connected to one of the grooves 210. Plating solution return passages 216 are connected at one ends thereof to the bottoms of all the grooves 210, and connected at the other ends thereof to a plating solution reservoir 218 which stores an overflowed plating solution and is opened to the air.

Thus, the provision of the labyrinth seal 212 comprising a plurality of grooves 210 around the inlet of the anode support 52 in the plating container 50 can eliminate the need to tighten the sealing member 200 with large forces, and can ensure reliable sealing of the gap between the plating container 50 and the anode support 52 to prevent the plating solution from leaking out. The inert gas introduction passage 214 is connected to one of the grooves 210, and the plating solution return passages 216 are connected to the bottoms of all the grooves 210. Inert gas such as nitrogen gas having a pressure high enough to discharge the plating solution remaining within the grooves 210 is introduced to the groove 210 through the inert gas introduction passage 214. Thus, the plating solution remaining within the grooves 210 can be discharged to the exterior, and the effect of the labyrinth seal 212 can be prevented from being deteriorated by the plating solution remaining within the grooves 210.

In this embodiment, the labyrinth seal 212 comprising a plurality of grooves 210 is provided on the plating container 50. Alternatively, the labyrinth seal may be provided on the anode support 52 or on both of the plating container 50 and the anode support side 52.

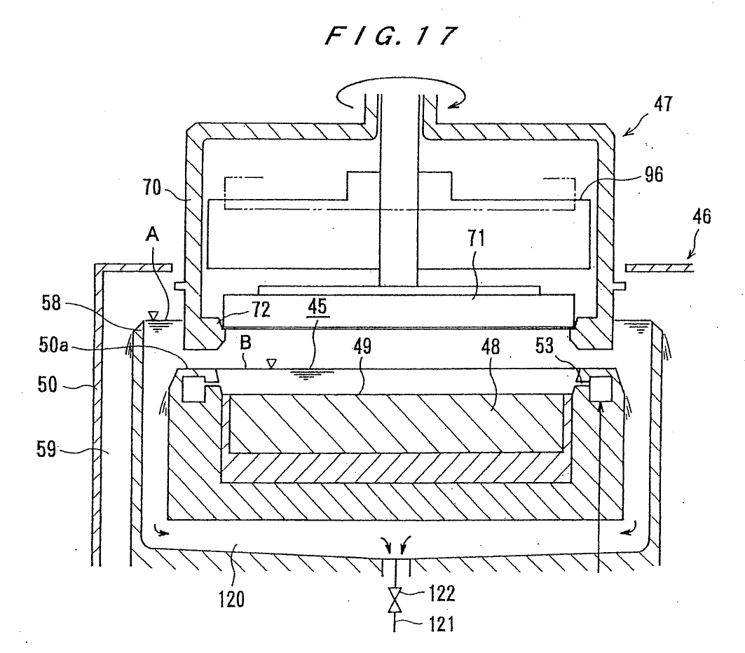

FIG. 17 is a vertical cross-sectional view schematically showing a plating unit according to still another embodiment of the present invention. In the plating unit 4 shown in FIG. 4, the transfer of the substrate is performed by moving the housing 70 up and down. In the plating unit of this embodiment, the liquid level of the plating solution within the plating process container is raised or lowered for transferring (receiving and withdrawing) the substrate without the vertical movement of the housing 70.

The plating unit comprises a plating process container 46 and a head 47. The plating container 50 of the plating process container 46 has, first plating solution discharge ports (not shown) which are located around the anode 48 and are opened at the bottom of the plating container 50, and second plating solution discharge ports 59 for discharging the plating solution 45 which have overflowed a weir member 58 in the plating container 50. Further, the plating container 50 has third plating solution discharge ports 120 which are opened at a step portion 50a provided at the halfway along the height direction of the circumferential wall of the weir member 58. A shut-off valve 122 is provided in a plating solution discharge pipe 121 extending from the third plating solution discharge ports 120 to the reservoir 226 (see FIG. 6).

With this construction, a plane defined by the upper end of the weir member 58 in the plating container 50 constitutes a liquid level A for plating the substrate, while a plane defined by the step portion 50a constitutes a liquid level B for transferring the substrate. Specifically, at the time of plating process, the shut-off valve 122 is closed, and the plating solution is ejected through the plating solution supply nozzles 53 to raise the liquid level of the plating solution 45 within the plating chamber 49. The plating solution overflows the upper end of the weir member 58 in the plating container 50, thereby maintaining the liquid level at the liquid level A for plating the substrate. After the completion of the plating process, the shut-off valve 122 is opened to discharge the plating solution 45 within the plating chamber 49 through the third plating solution discharge ports 120, for thereby bringing the liquid level to the liquid level B for transferring the substrate.

Thus, by immersing the anode 48 in the plating solution 45 in a period other than during the plating process, a black film formed on the surface of the anode 48 can be prevented from being dried and oxidized, and hence the plating process can be stably carried out.

When the substrate W is held by the substrate holding member 72 provided at the lower end of the housing 70, the housing 70 of the head 47 is not vertically movable, but is rotatable about its own axis, and the substrate W is located at a position between the liquid level A for plating the substrate and the liquid level B for transferring the substrate. The substrate table 71 is not provided with any mechanism for holding the substrate. The substrate W is placed on the substrate holding member 72 of the housing 70, and then the substrate table 71 is lowered to sandwich the peripheral portion of the substrate W between the substrate holding member 72 and the lower peripheral portion of the substrate table 71, for thereby holding the substrate W.

Next, a process of processing a substrate with the substrate processing apparatus having the plating unit will be described below. This embodiment is substantially the same as the above embodiments, except for transfer of the substrate through the second robot 3 and the process in the plating unit. Therefore, only the different construction and operation will be described below.

The substrate is transferred to the plating unit in the following manner: The suction-type hand of the second robot 3 and the substrate W held by the suction-type hand in such a manner the surface of the substrate faces downwardly are inserted into the housing 70 through the opening 96 of the housing 70. The suction-type hand is then moved downwardly, and the vacuum suction is released to place the substrate W on the substrate holding member 72 of the housing 70. Thereafter, the suction-type hand is lifted and withdrawn from the housing 70. Next, the substrate table 71 is lowered to sandwich the peripheral portion of the substrate W between the substrate holding member 72 and the lower peripheral portion of the substrate table 71, for thereby holding the substrate W.

Thereafter, the plating solution discharge pipe 121 connected to the third plating solution discharge ports 120 are closed by the shut-off valve 122, and the plating solution is ejected through the plating solution supply nozzles 53. At the same time, the housing 70 and the substrate W held by the housing 70 are rotated at a medium speed. After the plating solution reaches a predetermined level and several seconds have elapsed, the rotational speed of the housing 70 is lowered to a low rotational speed of 100 min⁻¹, for example, and a plating current is flowed, for thereby performing electroplating in such a state that the anode 48 serves as an anode and the surface, to be processed, of the substrate serves as a cathode.

After the completion of the supply of current, the shut-off valve 122 is opened to discharge, through the third plating solution discharge ports 120, the plating solution 45 present at a position above the step portion 50a to the reservoir 226. Thus, the housing 70 and the substrate held by the housing 70 are located above the liquid level of the plating solution and exposed to the atmosphere. In the state that the housing 70 and the substrate W held by the housing 70 are located above the liquid level of the plating solution, the housing 70 and the substrate W are rotated at a high speed of 500 to 800 min⁻¹, for example, to remove the plating solution from the substrate under a centrifugal force. After the completion of the removal of the plating solution from the substrate, the rotation of the housing 70 is stopped at a position where the housing 70 faces in a predetermined direction.

After the rotation of the housing 70 is completely stopped, the substrate table 71 is lifted to a substrate attaching/removing position. Next, the suction-type hand of the second robot 3 with the suction surface facing downwardly is inserted into the housing 70 through the opening 96 of the housing 70, and is lowered to a position where the suction-type hand can hold the substrate by suction. The substrate is then held by vacuum suction with the suction-type hand, and the suction-type hand is then moved to a position above the opening 96 of the housing 70. Thereafter, the suction-type hand and the substrate held by the suction-type hand are withdrawn from the housing 70 through the opening 96 of the housing 70.

According to this embodiment, the mechanism of the head 47 can be simplified and made compact. In addition, the plating process is carried out when the surface of the plating solution within the plating process container 46 is on a liquid level A for plating the substrate, while the substrate is dewatered and transferred when the surface of the plating solution is on a liquid level B for transferring the substrate. Further, it is possible to prevent a black film formed on the surface of the anode 48 from being dried and oxidized. Further, since the position of the substrate which is plated is the same as the position of the substrate from which an excessive plating solution is removed by rotation of the substrate, the position for performing mist-splash prevention can be lowered.

Furthermore, in this embodiment, the following process may be performed: When the surface of the plating solution is on the liquid level B for transferring the substrate, the substrate W is inserted into the housing 70 and held by the housing 70, and then the liquid level of the plating solution is raised to the liquid level A for plating the substrate. At the same time, the housing 70 is raised by a certain distance.

After the surface of the plating solution is raised to the liquid level A for plating the substrate, the housing 70 is rotated at a medium speed of 150 min⁻¹, for example, and lowered, so that the substrate W is brought into contact with the surface of the plating solution which rises at its central portion. Thus, air bubbles on the surface of the substrate can positively be removed therefrom.

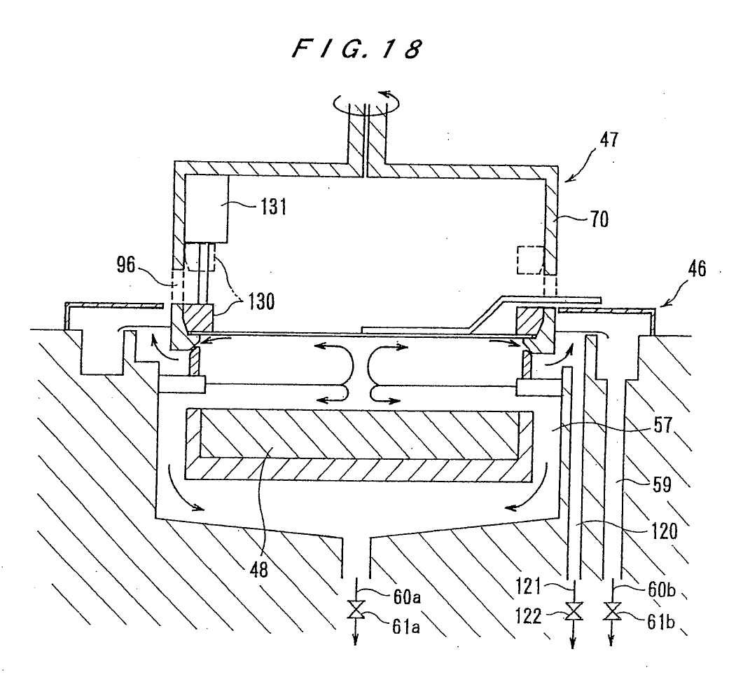

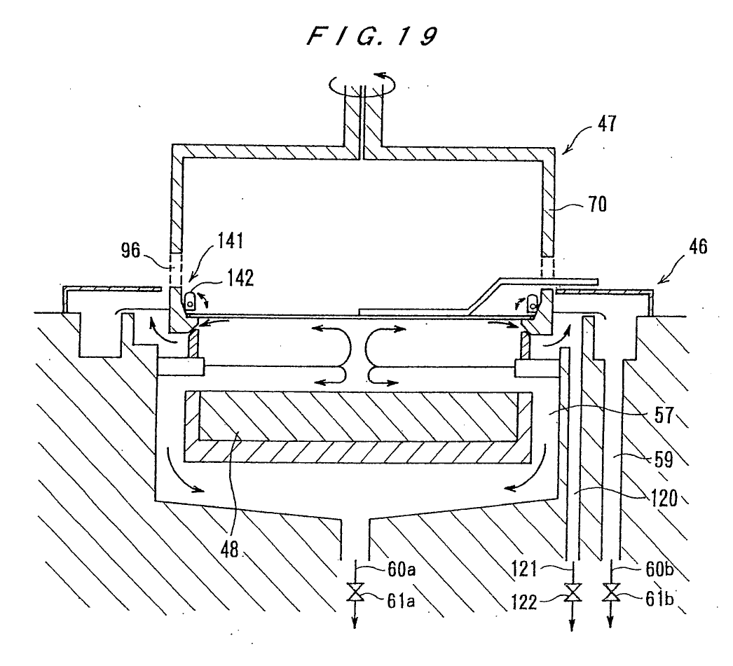

FIG. 18 is a vertical cross-sectional view schematically showing a plating unit according to still another embodiment of the present invention. The plating unit is different from the plating unit shown in FIG. 17 in that a pressing ring 130 is used, instead of the substrate table 71 constituting a pressing member for pressing the substrate of the plating unit shown in FIG. 17, and actuators 131 such as cylinders for vertically moving the pressing ring 130 are housed in the housing 70.

According to this embodiment, when the actuators 131 are actuated to lower the pressing ring 130, the peripheral portion of the substrate is sandwiched between the substrate holding member 72 of the housing 70 and the lower surface of the pressing ring 130, and hence the substrate W is held. The substrate can be released by lifting the pressing ring 130.

FIG. 19 is a vertical cross-sectional view schematically showing a plating unit according to still another embodiment of the present invention. The plating unit is different from the plating unit shown in FIG. 17 in that a clamp mechanism 141 having swing links 142 is used, instead of the substrate table 71 constituting a pressing member for pressing the substrate of the plating unit shown in FIG. 17, and the clamp mechanism 141 is housed within the housing 70 in its lower part.

According to this embodiment, when the swing links 142 are swung inwardly through the clamp mechanism 141 so as to be positioned in the horizontal direction, the peripheral portion of the substrate is sandwiched between the substrate holding member 72 of the housing 70 and the swing links 142, and hence the substrate W is held. When the swing links 142 are swung outwardly so as to be positioned in the vertical direction, the substrate is released. At the same time, it is possible to prevent the swing links 142 from hindering the withdrawal of the substrate W.

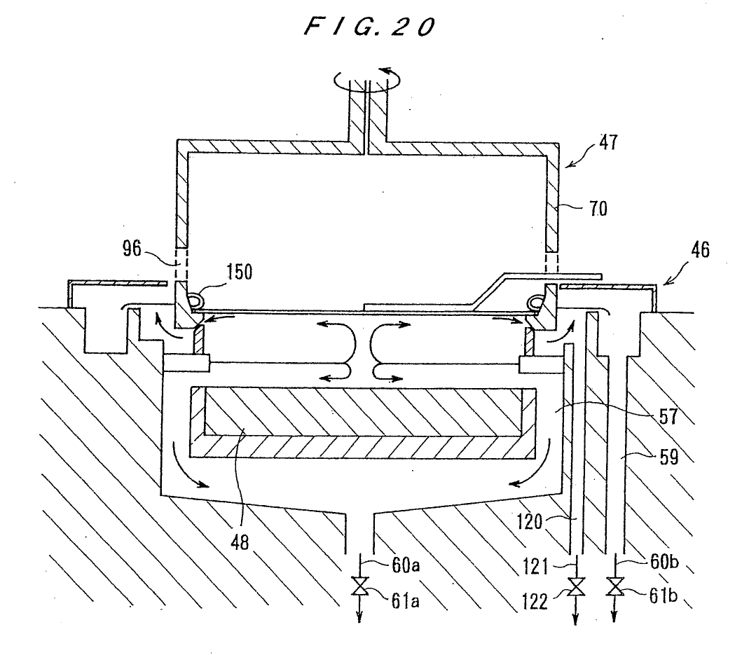

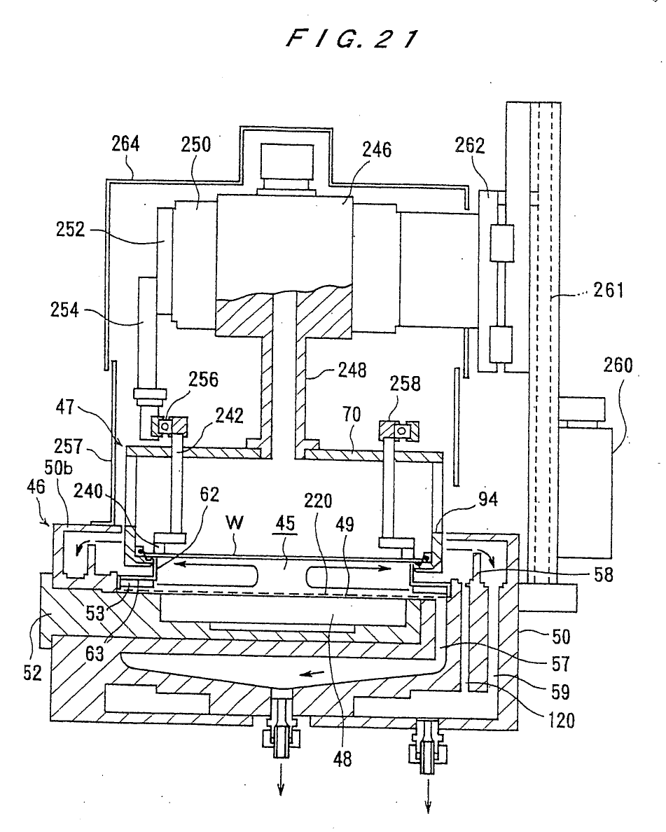

FIG. 20 is a vertical cross-sectional view schematically showing a plating unit according to still another embodiment of the present invention. The plating unit is different from the plating unit shown in FIG. 17 in that an elastic member 150 which is elastically deformable, i.e., expandable or contractable by pneumatic pressure is used, instead of the substrate table 71 constituting a pressing member for pressing the substrate of the plating unit shown in FIG. 17, and this elastic member 150 is housed within the housing 70 in its lower part.

According to this embodiment, by expanding the elastic member 150 by pneumatic pressure, the peripheral portion of the substrate is sandwiched between the substrate holding member 72 of the housing 70 and the elastic member 150, and hence the substrate W is held. The substrate can be released by discharging air from the elastic member 150. At the same time, it is possible to prevent the elastic member 150 from hindering the withdrawal of the substrate W.

FIGS. 21 through 23 are vertical cross-sectional views schematically showing a plating unit according to still another embodiment of the present invention. As shown in FIG. 21, the plating unit mainly comprises a plating process container 46 which is substantially cylindrical and contains a plating solution 45 therein., and a head 47 disposed above the plating process container 46 for holding the substrate W. In FIG. 21, the plating unit is in such a state that the substrate W is held by the head 47 and the surface of the plating solution 45 is on the liquid level for plating the substrate.

The plating process container 46 has a plating chamber 49 which is opened upwardly and has an anode 48 at the bottom thereof. A plating container 50 containing the plating solution 45 is provided within the plating chamber 49. Plating solution supply nozzles 53, which project horizontally toward the center of the plating chamber 49, are disposed at circumferentially equal intervals on the inner circumferential wall of the plating container 50. The plating solution supply nozzles 53 communicate with plating solution supply passages 54 (see FIG. 4) extending vertically within the plating container 50.

As shown in FIG. 6, the plating solution supply passages 54 are connected to the plating solution regulating tank 40 through the plating solution supply pipes 55. Control valves 56 for controlling the back pressure so as to be constant are disposed on each of the plating solution supply pipes 55.

Further, according to this embodiment, a punch plate 220 having a large number of holes with a size of about 3 mm, for example, is disposed at a position above the anode 48 within the plating chamber 49. The punch plate 220 prevents a black film formed on the surface of the anode 48 from curling up by the plating solution 45 and consequently being flowed out.

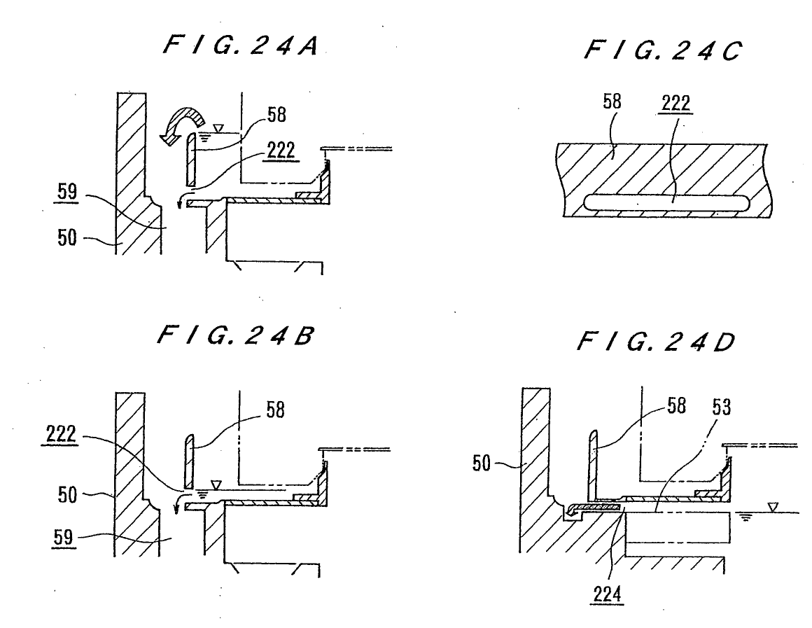

The plating container 50 has first plating solution discharge ports 57 for withdrawing the plating solution 45 contained in the plating chamber 49 from the peripheral portion of the bottom in the plating chamber 49, and second plating solution discharge ports 59 for discharging the plating solution 45 which has overflowed a weir member 58 provided at the upper end of the plating container 50. Further, the plating container 50 has third plating solution discharge ports 120 for discharging the plating solution before overflowing the weir member 58. The plating solution which has flowed through the second plating solution discharge ports 59 and the third plating solution discharge ports 120 join at the lower end of the plating container 50, and then are discharged from the plating container 50. Instead of providing the third plating solution discharge ports 120, as shown in FIGS. 24A and 24C, the weir member 58 may have, in its lower part, openings 222 having a predetermined width at predetermined intervals so that the plating solution 45 passes through the openings 222 and is then discharged to the second plating solution discharge ports 59.

With this arrangement, when the amount of plating solution supplied is large during plating, the plating solution is discharged to the exterior through the third plating solution discharge ports 120 or is passed through the openings 222 and discharged to the exterior through the second plating solution discharge ports 59. Further, as shown in FIG. 24A, the plating solution overflows the weir member 58 and is discharged to the exterior through the second plating solution discharge ports 59. On the other hand, during plating, when the amount of plating solution supplied is small, the plating solution is discharged to the exterior through the third plating solution discharge ports 120, or alternatively as shown in FIG. 24B, the plating solution is passed through the openings 222 and discharged to the exterior through the second plating solution discharge ports 59. In this manner, this construction can easily cope with the case where the amount of plating solution supplied is large or small.

Further, as shown in FIG. 24D, through holes 224 for controlling the liquid level, which are located above the plating solution supply nozzles 53 and communicate with the plating chamber 49 and the second plating solution discharge ports 59, are provided at circumferentially predetermined pitches. Thus, when plating is not performed, the plating solution is passed through the through holes 224, and is discharged to the exterior through the second plating solution discharge ports 59, for thereby controlling the liquid level of the plating solution. During plating, the through holes 224 serve as an orifice for restricting the amount of the plating solution flowing therethrough.

As shown in FIG. 6, the first plating solution discharge ports 57 are connected to the reservoir 226 through the plating solution discharge pipe 60a, and a flow controller 61a is provided in the plating solution discharge pipe 60a. The second plating solution discharge ports 59 and the third plating solution discharge ports 120 join to each other within the plating container 50, and the joined passage is then connected directly to the reservoir 226 through the plating solution discharge pipe 60b.

The reservoir 226 is constructed so that the plating solution from all the other plating units flows into the reservoir 226. The plating solution which has flowed into the reservoir 226 is introduced by a pump 228 into the plating solution regulating tank 40 (see FIG. 6). This plating solution regulating tank 40 is provided with a temperature controller 230, and a plating solution analyzing unit 232 for sampling the plating solution and analyzing the sample liquid.

When a single pump 234 is operated, the plating solution is supplied from the plating solution regulating tank 40 through the filter 236 to the plating solution supply nozzles 53 in each of the plating units. A control valve 56 is provided in the plating solution supply pipe 55 extending from the plating solution regulating tank 40 to each of the plating units. This control valve 56 serves to make the pressure on the secondary side constant, and, even when one plating unit is stopped, the control valve 56 can make the supply pressure of the plating solution in the other plating units constant.

Thus, a plating solution prepared in a plating solution regulating tank 40 in a single plating process system is supplied to a plurality of plating units through the single pump 234. The plating solution preparation tank 40 having a large capacity is used in the plating process system to prepare a plating solution. With this arrangement, the plating solution is supplied to each of the plating units while controlling the flow rate in each of the plating units through control valves 56, and a variation of the plating solution in quality can be suppressed.

A vertical stream regulating ring 62 and a horizontal stream regulating ring 63 are disposed within the plating chamber 49 at a position near the internal circumference of the plating chamber 49, and the central portion of the liquid surface is pushed up by an upward stream out of two divided upward and downward streams of the plating solution 45 within the plating chamber 49, so that the downward flow is smoothened and the distribution of the current density is further uniformized. The horizontal stream regulating ring 63 has a peripheral portion which is fixed to the plating container 50, and the vertical stream regulating ring 62 is connected to the horizontal stream regulating ring 63.

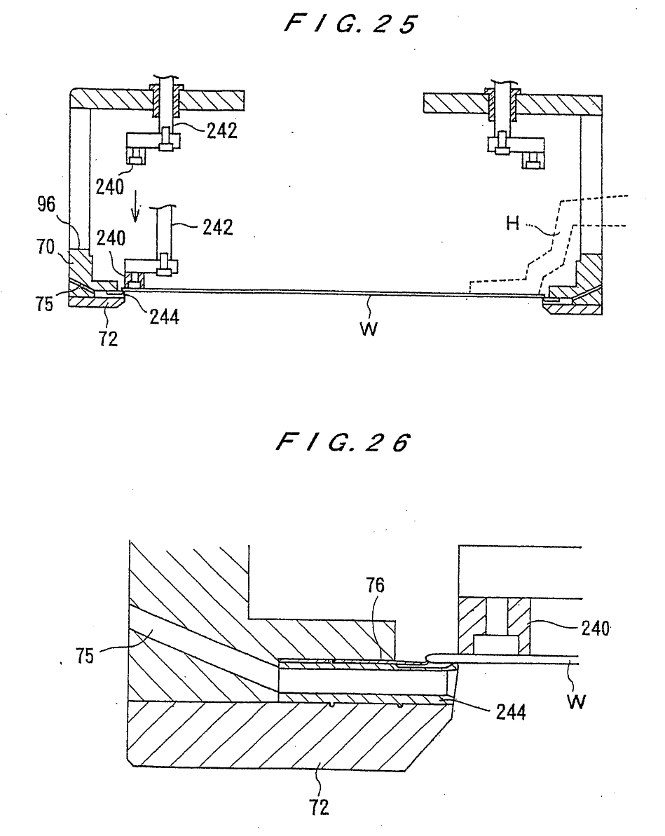

On the other hand, the head 47 comprises a housing 70 which is a rotatable and cylindrical receptacle having a downwardly open end and has openings 96 on the circumferential wall, and vertically movable pressing rods 242 having, in its lower end, a pressing ring 240. As shown in FIGS. 25 and 26, an inwardly projecting ring-shaped substrate holding member 72 is provided at the lower end of the housing 70. A ring-shaped sealing member 244 is mounted on the substrate holding member 72. The ring-shaped sealing member 244 projects inwardly, and the front end of the top surface in the ring-shaped sealing member 244 projects upwardly in an annular tapered form. Further, contacts 76 for a cathode electrode are disposed above the sealing member 244. Air vent holes 75, which extend outwardly in the horizontal direction and further extend outwardly in an upwardly inclined state, are provided in the substrate holding member 72 at circumferentially equal intervals. The contacts 76 for a cathode electrode and the air vent holes 75 are the same as those shown in FIG. 4.

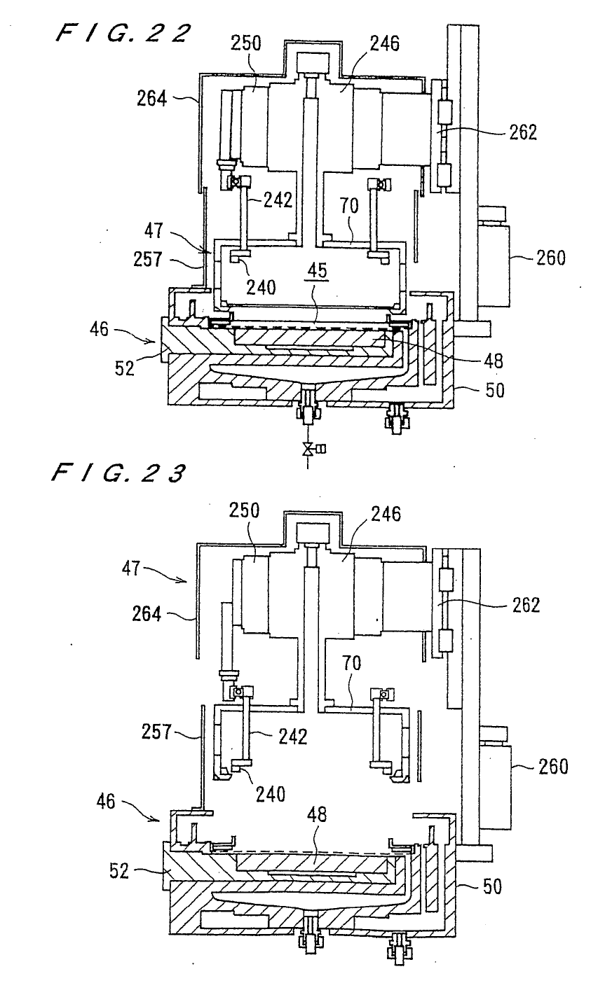

With this arrangement, in such a state that the liquid level of the plating solution is lowered as shown in FIG. 22, the substrate W is held by a robot hand H or the like and inserted into the housing 70, where the substrate W is placed on the upper surface of the sealing member 244 of the substrate holding member 72, as shown in FIGS. 25 and 26. Thereafter, the robot hand H is withdrawn from the housing 70, and the pressing ring 240 is then lowered to sandwich the peripheral portion of the substrate W between the sealing member 244 and the lower surface of the pressing ring 240, for thereby holding the substrate W. In addition, upon holding of the substrate W, the lower surface of the substrate W is brought into pressure contact with the sealing member 244 to seal this contact portion positively. At the same time, a current flows between the substrate W and the contacts 76 for a cathode electrode.

As shown in FIG. 21, the housing 70 is coupled to an output shaft 248 of a motor 246, and rotated by energization of the motor 246. The pressing rods 242 are vertically provided at predetermined positions along the circumferential direction of a ring-shaped support frame 258 rotatably mounted through a bearing 256 on the lower end of a slider 254. The slider 254 is vertically movable by actuation of a cylinder 252, with a guide, fixed to a support 250 surrounding the motor 246. With this construction, the pressing rods 242 are vertically movable by the actuation of the cylinder 252, and, in addition, upon the holding of the substrate W, the pressing rods 242 are rotated integrally with the housing 70.

The support 250 is mounted on a slide base 262 which is engaged with a ball screw 261 and vertically movable by the ball screw 261 rotated by energization of the motor 260. The support 250 is surrounded by an upper housing 264, and is vertically movable together with the upper housing 264 by energization of the motor 260. Further, a lower housing 257 for surrounding the housing 70 during plating is mounted on the upper surface of the plating container 50.

With this construction, as shown in FIG. 22, maintenance can be performed in such a state that the support 250 and the upper housing 264 are lifted. A crystal of the plating solution is likely to deposit on the inner circumferential surface of the weir member 58. However, the support 250 and the upper housing 264 are lifted, a large amount of the plating solution is flowed and overflows the weir member 58, and hence the crystal of the plating solution is prevented from being deposited on the inner circumferential surface of the weir member 58. A cover 50b for preventing the splash of the plating solution is integrally provided in the plating container 50 to cover a portion above the plating solution which overflows during plating process. By coating an ultra-water-repellent material such as HIREC (manufactured by NTT Advance Technology Inc.) on the lower surface of the cover 50b for preventing the splash of the plating solution, the crystal of the plating solution can be prevented from being deposited on the lower surface of the cover 50b.

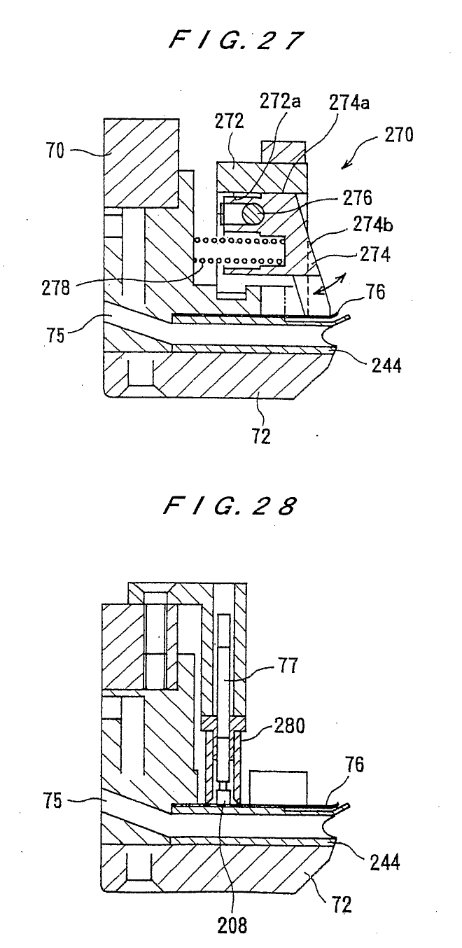

Substrate centering mechanisms 270 located above the substrate holding member 72 of the housing 70 for performing centering of the substrate W are provided at four places along the circumferential direction in this embodiment. FIG. 27 shows the substrate centering mechanism 270 in detail. The substrate centering mechanism 270 comprises a gate-like bracket 272 fixed to the housing 70, and a positioning block 274 disposed within the bracket 272. This positioning block 274 is swingably mounted through a support shaft 276 horizontally fixed to the bracket 272. Further, a compression coil spring 278 is interposed between the housing 70 and the positioning block 274. Thus, the positioning block 274 is urged by the compression coil spring 278 so that the positioning block 274 rotates about the support shaft 276 and the lower portion of the positioning block 274 projects inwardly. The upper surface 274a of the positioning block 274 serves as a stopper, and is brought into contact with the lower surface 272a of the bracket 272 to restrict the movement of the positioning block 274. Further, the positioning block 274 has a tapered inner surface 274b which is widened outwardly in the upward direction.

With this construction, a substrate is held by the hand of a transfer robot or the like, is transferred into the housing 70, and is placed on the substrate holding member 72. In this case, when the center of the substrate deviates from the center of the substrate holding member 72, the positioning block 274 is rotated outwardly against the urging force of the compression coil spring 278 and, upon the release of holding of the substrate from the hand of the transfer robot or the like, the positioning block 274 is returned to the original position by the urging force of the compression coil spring 278. Thus, the centering of the substrate can be carried out.

FIG. 28 shows a feeding contact (a probe) 77 for feeding power to a cathode electrode plate 208 of a contact 76 for a cathode electrode. This feeding contact 77 is composed of a plunger and is surrounded by a cylindrical protective member 280 extending to the cathode electrode plate 208, so that the feeding contact 77 is protected against the plating solution.

In the substrate processing apparatus having the plating unit as described above, when the surface of the plating solution is on a low level for transferring the substrate as shown in FIG. 22, the substrate is inserted into and held within the housing 70. In this state, the liquid level of the plating solution is raised and the substrate is plated. Thereafter, the liquid level of the plating solution is lowered, and the plated substrate is withdrawn from the housing 70. Further, maintenance is carried out in such a state that the support 250 and the upper housing 264 are lifted. In this state, if necessary, a large amount of the plating solution is flowed to overflow the weir member 58, for thereby preventing a crystal of the plating solution from being deposited on the inner circumferential surface of the weir member 58.

Further, in this embodiment, the following process may be performed in the following manner: When the surface of the plating solution is on the liquid level B for transferring the substrate, the substrate W is inserted into the housing 70 and held by the housing 70, and then the liquid level of the plating solution is raised to the liquid level A for plating the substrate. At the same time, the housing 70 is lifted by a certain distance. After the liquid level of the polishing liquid reaches the liquid level A for plating the substrate, the housing 70 is rotated at a medium speed of 150 min⁻¹, for example, and lowered, so that the substrate W is brought into contact with the surface of the plating solution which is raised at its central portion. Thus, air bubbles on the surface of the substrate can be positively removed therefrom.

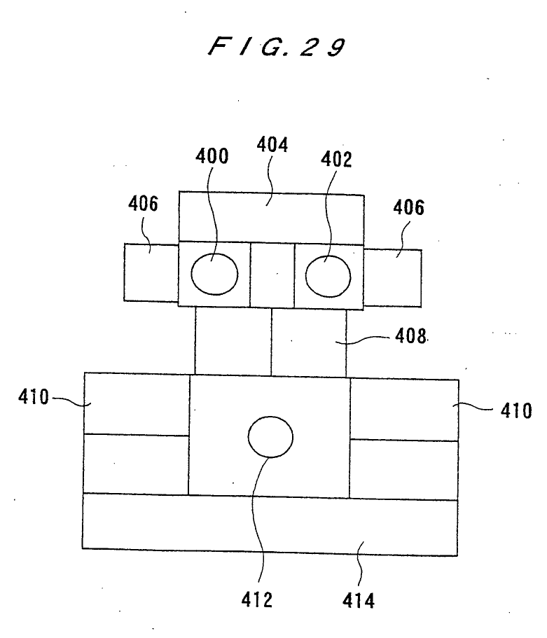

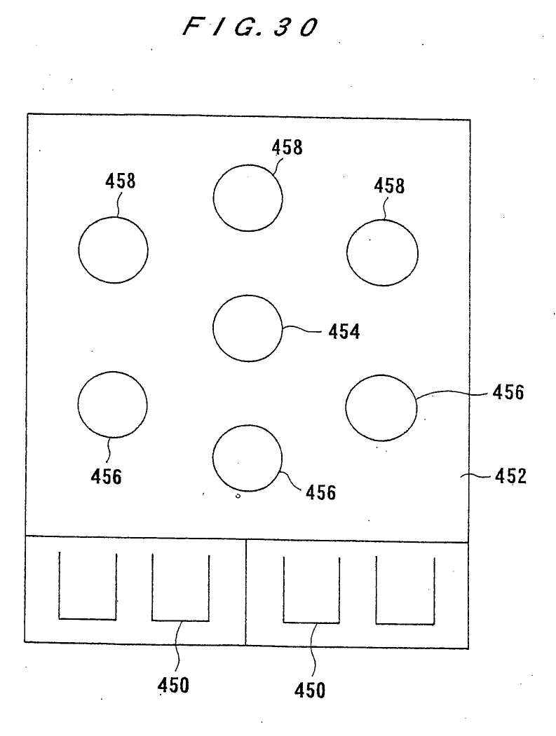

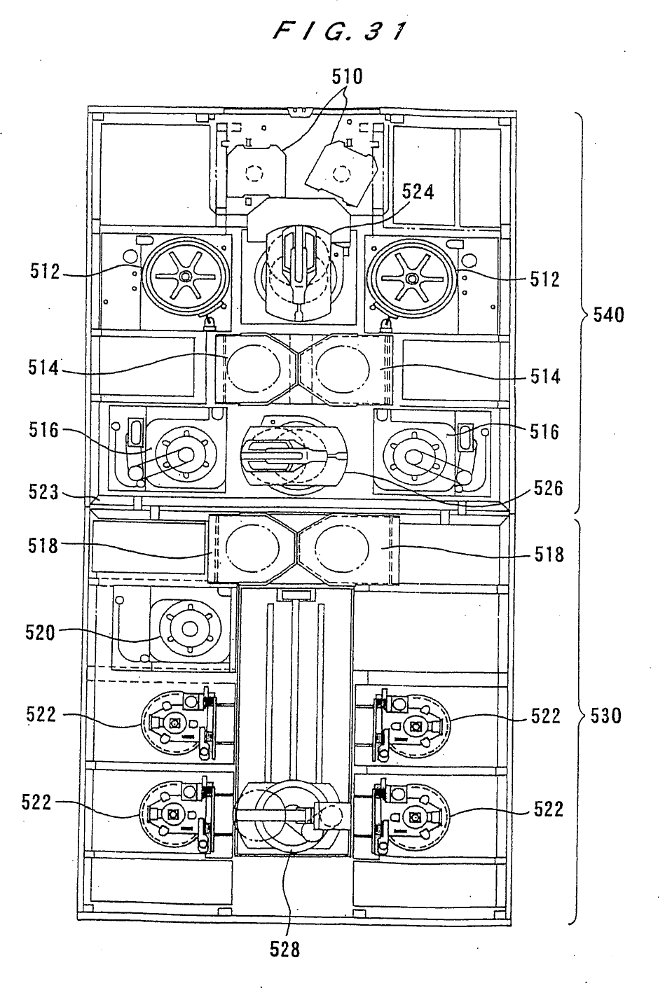

In the above embodiments, the plating units 4 are disposed on one side of the second robot 3. However, the present invention is not limited thereto. For example, the plating units are disposed in such arrangements as shown in FIGS. 29 and 30.

The plating apparatus shown in FIG. 29 comprises a loading/unloading unit 404, four plating units 410, a first robot 400, a second robot 402, a third robot 412, two annealing units 406, and two cleaning units 408 (spinning-rinsing-drying units and/or bevel-etching/chemical cleaning units). The loading/unloading unit 404, the two annealing units 406, and the cleaning units 408 are disposed around the first robot 400 and the second robot 402. Further, the third robot 412 is disposed at the position surrounded by the cleaning units 408 and the four plating units 410. The apparatus is also provided with a chemical liquid supplying system 414 for supplying the plating solution to the plating units 410. In this case, the plating units 410 and the chemical liquid supplying system 414 are disposed in a plating section isolated by a partition wall (not shown) from a processing section where the other units (annealing units 406 and cleaning units 408) are disposed.

The plating apparatus shown in FIG. 30 comprises loading/unloading units 450 and a processing section 452. From the viewpoint of the throughput of semiconductor wafers or the like, a transfer device 454 is disposed in the center of the processing section 452, and a plurality of plating units 456 and a plurality of cleaning/drying units (spinning-rinsing-drying units) 458 are disposed around the transfer device 454. In this embodiment, three plating units 456 and three cleaning/drying units 458 are disposed around one transfer device 454. Instead of the cleaning/drying units 456, bevel-etching/chemical cleaning units may be disposed. The plating unit 456 may be either of the face-up type or of the face-down type. In this case, the plating units 456 are disposed in a plating section isolated by a partition wall (not shown) from a processing section where the other units (cleaning/drying units 458) are disposed.

In the above embodiments, although examples in which the plated Cu film is formed by electroplating have been described, plating is not limited to Cu plating. A substrate may be plated with Cu alloy or other metal. The plated film may be formed by an electroless plating method. The plating unit may be either of the face-up type or of the face-down type.

FIG. 31 is a plan view of an example of a substrate plating apparatus. The substrate plating apparatus comprises loading/unloading units 510, each pair of cleaning/drying units 512, first substrate stages 514, bevel-etching/chemical cleaning units 516 and second substrate stages 518, a washing unit 520 provided with a mechanism for reversing the substrate through 180°, and four plating units 522. The substrate plating apparatus is also provided with a first transfer device 524 for transferring a substrate between the loading/unloading units 510, the cleaning/drying units 512 and the first substrate stages 514, a second transfer device 526 for transferring a substrate between the first substrate stages 514, the bevel-etching/chemical cleaning units 516 and the second substrate stages 518, and a third transfer device 528 for transferring the substrate between the second substrate stages 518, the washing unit 520 and the plating units 522.

The substrate plating apparatus has a partition wall 523 for dividing the plating apparatus into a plating section 530 and a clean space 540. Air can individually be supplied into and exhausted from each of the plating section 530 and the clean space 540. The partition wall 523 has a shutter (not shown) capable of opening and closing. The pressure of the clean space 540 is lower than the atmospheric pressure and higher than the pressure of the plating section 530. This can prevent the air in the clean space 540 from flowing out of the plating apparatus and can prevent the air in the plating section 530 from flowing into the clean space 540.

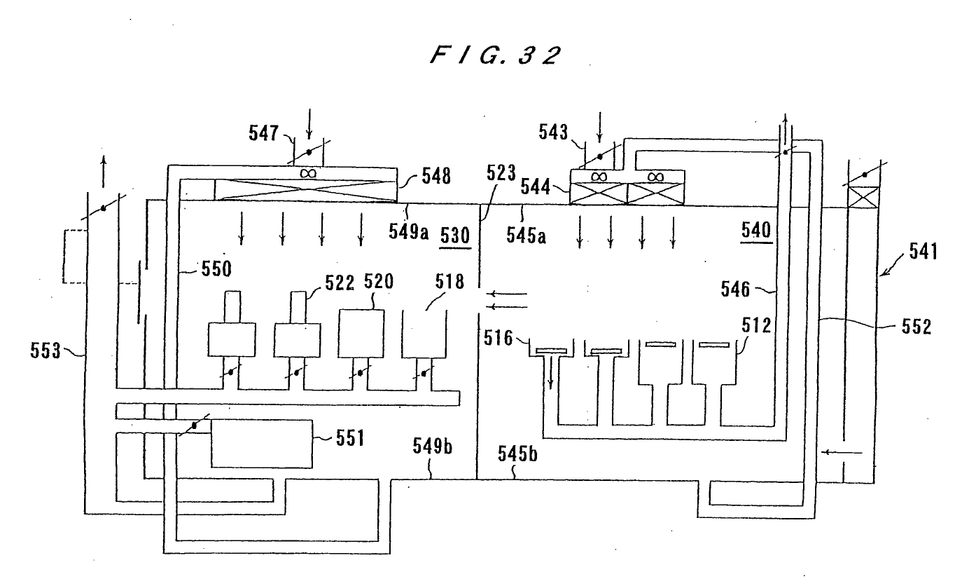

FIG. 32 is a schematic view showing an air current in the substrate plating apparatus. In the clean space 540, a fresh external air is introduced through a pipe 543 and pushed into the clean space 540 through a high-performance filter 544 by a fan. Hence, a down-flow clean air is supplied from a ceiling 545a to positions around the cleaning/drying units 512 and the bevel-etching/chemical cleaning units 516. A large part of the supplied clean air is returned from a floor 545b through a circulation pipe 552 to the ceiling 545a, and pushed again into the clean space 540 through the high-performance filter 544 by the fan, to thus circulate in the clean space 540. A part of the air is discharged from the cleaning/drying units 512 and the bevel-etching/chemical cleaning units 516 through a pipe 546 to the exterior, so that the pressure of the clean space 540 is set to be lower than the atmospheric pressure.

The plating section 530 having the washing units 520 and the plating units 522 therein is not a clean space (but a contamination zone). However, it is not acceptable to attach particles to the surface of the substrate. Therefore, in the plating section 530, a fresh external air is introduced through a pipe 547, and a down-flow clean air is pushed into the plating section 530 through a high-performance filter 548 by a fan, for thereby preventing particles from being attached to the surface of the substrate. However, if the whole flow rate of the down-flow clean air is supplied by only an external air supply and exhaust, then enormous air supply- and exhaust are required. Therefore, the air is discharged through a pipe 553 to the exterior, and a large part of the down-flow is supplied by a circulating air through a circulation pipe 550 extended from a floor 549b, in such a state that the pressure of the plating section 530 is maintained to be lower than the pressure of the clean space 540.

Thus, the air returned to a ceiling 549a through the circulation pipe 550 is pushed again into the plating section 530 through the high-performance filter 548 by the fan. Hence, a clean air is supplied into the plating section 530 to thus circulate in the plating section 530. In this case, air containing chemical mist or gas emitted from the washing units 520, the plating units 522, the third transfer device 528, and a plating solution regulating bath 551 is discharged through the pipe 553 to the exterior. Thus, the pressure of the plating section 530 is controlled so as to be lower than the pressure of the clean space 540.

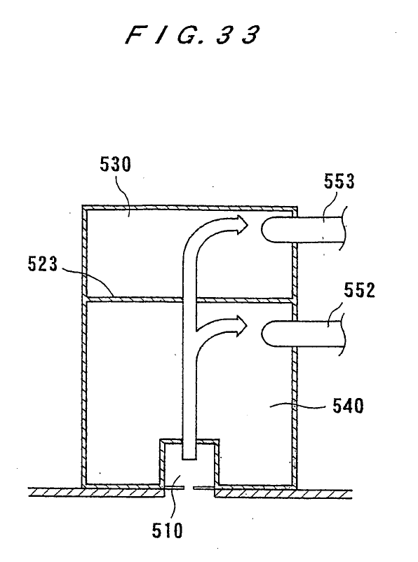

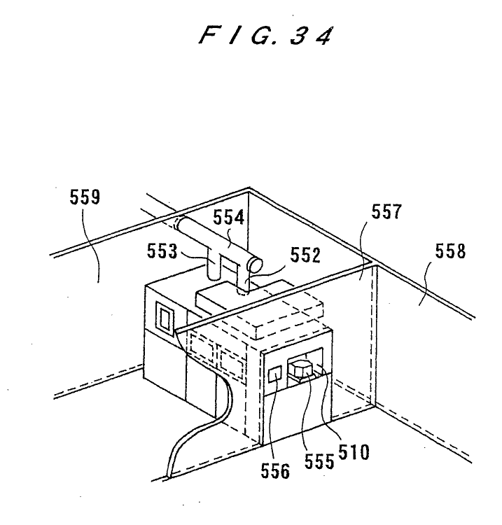

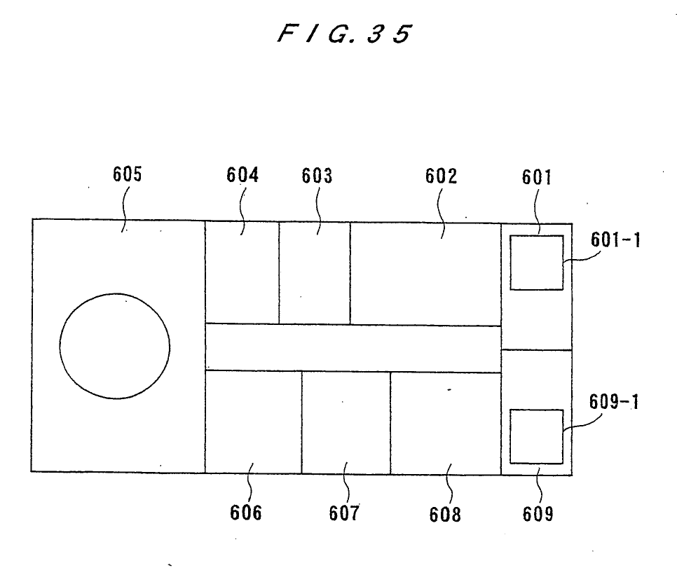

The pressure in the loading/unloading units 510 is higher than the pressure in the clean space 540 which is higher than the pressure in the plating section 530. When the shutters (not shown) are opened, therefore, air flows successively through the loading/unloading units 510, the clean space 540, and the plating section 530, as shown in FIG. 33. Air discharged from the clean space 540 and the plating section 530 flows through the ducts 552, 553 into a common duct 554 (see FIG. 34) which extends out of the clean room.

FIG. 34 shows in perspective the substrate plating apparatus shown in FIG. 31, which is placed in the clean room. The loading/unloading units 510 includes a side wall which has a cassette transfer port 555 defined therein and a control panel 556, and which is exposed to a working zone 558 that is compartmented in the clean room by a partition wall 557. The partition wall 557 also compartments a utility zone 559 in the clean room in which the substrate plating apparatus is installed. Other sidewalls of the substrate plating apparatus are exposed to the utility zone 559 whose air cleanness is lower than the air cleanness in the working zone 558.

FIG. 35 is a plan view of another example of a substrate plating apparatus. The substrate plating apparatus shown in FIG. 35 comprises a loading unit 601 for loading a semiconductor substrate, a copper plating chamber 602 for plating a semiconductor substrate with copper, a pair of water cleaning chambers 603, 604 for cleaning a semiconductor substrate with water, a chemical mechanical polishing unit 605 for chemically and mechanically polishing a semiconductor substrate, a pair of water cleaning chambers 606, 607 for cleaning a semiconductor substrate with water, a drying chamber 608 for drying a semiconductor substrate, and an unloading unit 609 for unloading a semiconductor substrate with an interconnection film thereon. The substrate plating apparatus also has a substrate transfer mechanism (not shown) for transferring semiconductor substrates to the chambers 602, 603, 604, the chemical mechanical polishing unit 605, the chambers 606, 607, 608, and the unloading unit 609. The loading unit 601, the chambers 602, 603, 604, the chemical mechanical polishing unit 605, the chambers 606, 607, 608, and the unloading unit 609 are combined into a single unitary arrangement as an apparatus.

The substrate plating apparatus operates as follows: The substrate transfer mechanism transfers a semiconductor substrate W on which an interconnection film has not yet been formed from a substrate cassette 601-1 placed in the loading unit 601 to the copper plating chamber 602. In the copper plating chamber 602, a plated copper film is formed on a surface of the semiconductor substrate W having an interconnection region composed of an interconnection trench and an interconnection hole (contact hole).

After the plated copper film is formed on the semiconductor substrate W in the copper plating chamber 602, the semiconductor substrate W is transferred to one of the water cleaning chambers 603, 604 by the substrate transfer mechanism and cleaned by water in one of the water cleaning chambers 603, 604. The cleaned semiconductor substrate W is transferred to the chemical mechanical polishing unit 605 by the substrate transfer mechanism. The chemical mechanical polishing unit 605 removes the unwanted plated copper film from the surface of the semiconductor substrate W, leaving a portion of the plated copper film in the interconnection trench and the interconnection hole. A barrier layer made of TiN or the like is formed on the surface of the semiconductor substrate W, including the inner surfaces of the interconnection trench and the interconnection hole, before the plated copper film is deposited.

Then, the semiconductor substrate W with the remaining plated copper film is transferred to one of the water cleaning chambers 606, 607 by the substrate transfer mechanism and cleaned by water in one of the water cleaning chambers 606, 607. The cleaned semiconductor substrate W is then dried in the drying chamber 608, after which the dried semiconductor substrate W with the remaining plated copper film serving as an interconnection film is placed into a substrate cassette 609-1 in the unloading unit 609.

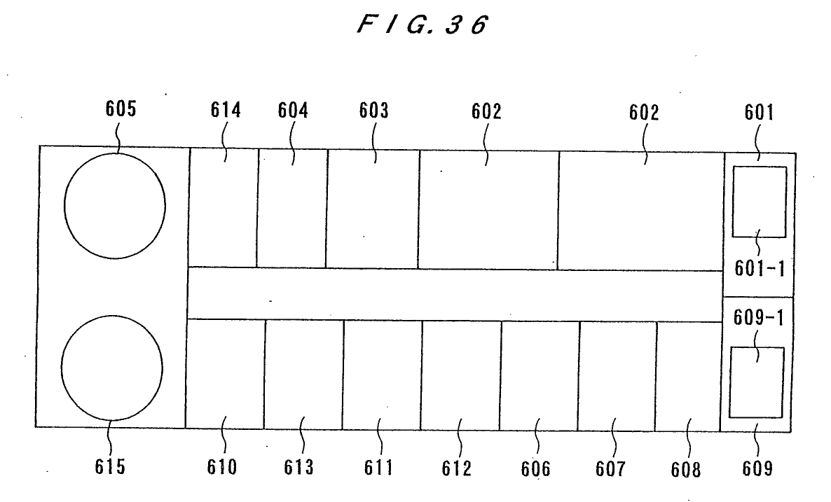

FIG. 36 shows a plan view of still another example of a substrate plating apparatus. The substrate plating apparatus shown in FIG. 36 differs from the substrate plating apparatus shown in FIG. 35 in that it additionally includes a copper plating chamber 602, a water cleaning chamber 610, a pretreatment chamber 611, a protective layer plating chamber 612 for forming a protective plated layer on a plated copper film on a semiconductor substrate, water cleaning chambers 613, 614, and a chemical mechanical polishing unit 615. The loading unit 601, the chambers 602, 602, 603, 604, 614, the chemical mechanical polishing unit 605, 615, the chambers 606, 607, 608, 610, 611, 612, 613, and the unloading unit 609 are combined into a single unitary arrangement as an apparatus.

The substrate plating apparatus shown in FIG. 36 operates as follows: A semiconductor substrate W is supplied from the substrate cassette 601-1 placed in the loading unit 601 successively to one of the copper plating chambers 602, 602. In one of the copper plating chamber 602, 602, a plated copper film is formed on a surface of a semiconductor substrate W having an interconnection region composed of an interconnection trench and an interconnection hole (contact hole). The two copper plating chambers 602, 602 are employed to allow the semiconductor substrate W to be plated with a copper film for a long period of time. Specifically, the semiconductor substrate W may be plated with a primary copper film according to electroless plating in one of the copper plating chamber 602, and then plated with a secondary copper film according to electroplating in the other copper plating chamber 602. The substrate plating apparatus may have more than two copper plating chambers.

The semiconductor substrate W with the plated copper film formed thereon is cleaned by water in one of the water cleaning chambers 603, 604. Then, the chemical mechanical polishing unit 605 removes the unwanted portion of the plated copper film from the surface of the semiconductor substrate W, leaving a portion of the plated copper film in the interconnection trench and the interconnection hole.

Thereafter, the semiconductor substrate W with the remaining plated copper film is transferred to the water cleaning chamber 610, in which the semiconductor substrate W is cleaned with water. Then, the semiconductor substrate W is transferred to the pretreatment chamber 611, and pretreated therein for the deposition of a protective plated layer. The pretreated semiconductor substrate W is transferred to the protective layer-plating chamber 612. In the protective layer plating chamber 612, a protective plated layer is formed on the plated copper film in the interconnection region on the semiconductor substrate W. For example, the protective plated layer is formed with an alloy of nickel (Ni) and boron (B) by electroless plating.

After semiconductor substrate is cleaned in one of the water cleaning chambers 613, 614, an upper portion of the protective plated layer deposited on the plated copper film is polished off to planarize the protective plated layer, in the chemical mechanical polishing unit 615.

After the protective plated layer is polished, the semiconductor substrate W is cleaned by water in one of the water cleaning chambers 606, 607, dried in the drying chamber 608, and then transferred to the substrate cassette 609-1 in the unloading unit 609.

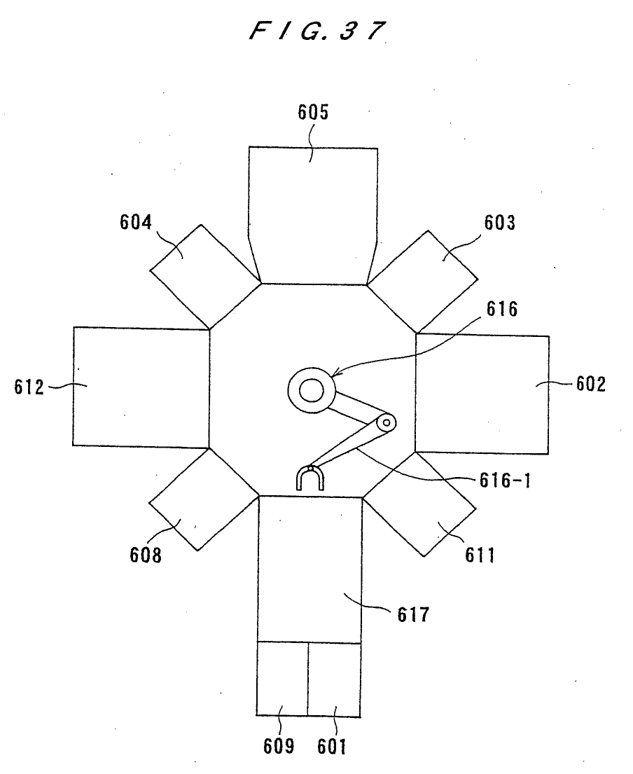

FIG. 37 is a plan view of still another example of a substrate plating apparatus. As shown in FIG. 37, the substrate plating apparatus includes a robot 616 at its center which has a robot arm 616-1, and also has a copper plating chamber 602, a pair of water cleaning chambers 603, 604, a chemical mechanical polishing unit 605, a pretreatment chamber 611, a protective layer plating chamber 612, a drying chamber 608, and a loading/unloading station 617 which are disposed around the robot 616 and positioned within the reach of the robot arm 616-1. A loading unit 601 for loading semiconductor substrates and an unloading unit 609 for unloading semiconductor substrates are disposed adjacent to the loading/unloading station 617. The robot 616, the chambers 602, 603, 604, the chemical mechanical polishing unit 605, the chambers 608, 611, 612, the loading/unloading station 617, the loading unit 601, and the unloading unit 609 are combined into a single unitary arrangement as an apparatus.

The substrate plating apparatus shown in FIG. 37 operates as follows:

A semiconductor substrate to be plated is transferred from the loading unit 601 to the loading/unloading station 617, from which the semiconductor substrate is received by the robot arm 616-1 and transferred thereby to the copper plating chamber 602. In the copper plating chamber 602, a plated copper film is formed on a surface of the semiconductor substrate which has an interconnection region composed of an interconnection trench and an interconnection hole. The semiconductor substrate with the plated copper film formed thereon is transferred by the robot arm 616-1 to the chemical mechanical polishing unit 605. In the chemical mechanical polishing unit 605., the plated copper film is removed from the surface of the semiconductor substrate W, leaving a portion of the plated copper film in the interconnection trench and the interconnection hole.

The semiconductor substrate is then transferred by the robot arm 616-1 to the water-cleaning chamber 604, in which the semiconductor substrate is cleaned by water. Thereafter, the semiconductor substrate is transferred by the robot arm 616-1 to the pretreatment chamber 611, in which the semiconductor substrate is pretreated therein for the deposition of a protective plated layer. The pretreated semiconductor substrate is transferred by the robot arm 616-1 to the protective layer plating chamber 612. In the protective layer plating chamber 612, a protective plated layer is formed on the plated copper film in the interconnection region on the semiconductor substrate W. The semiconductor substrate with the protective plated layer formed thereon is transferred by the robot arm 616-1 to the water cleaning chamber 604, in which the semiconductor substrate is cleaned by water. The cleaned semiconductor substrate is transferred by the robot arm 616-1 to the drying chamber 608, in which the semiconductor substrate is dried. The dried semiconductor substrate is transferred by the robot arm 616-1 to the loading/unloading station 617, from which the plated semiconductor substrate is transferred to the unloading unit 609.

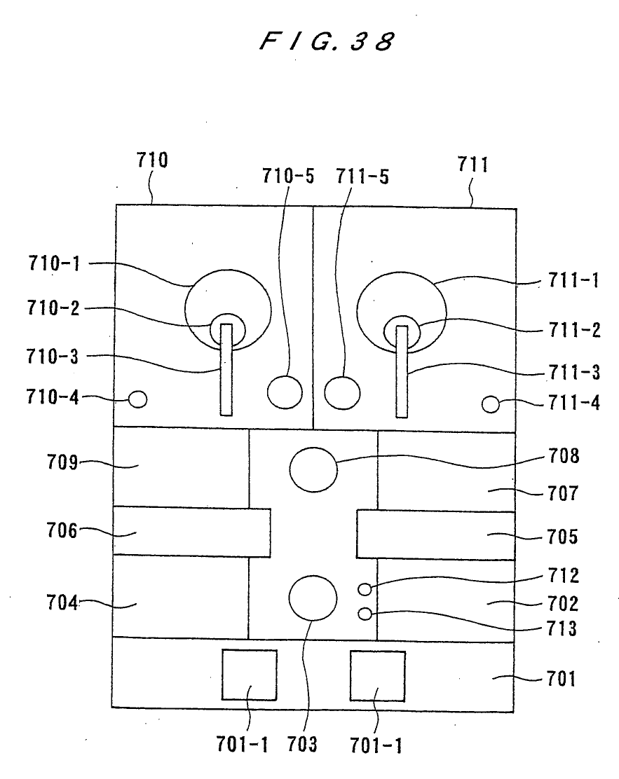

FIG. 38 is a view showing the plan constitution of another example of a semiconductor substrate processing apparatus. The semiconductor substrate processing apparatus is of a constitution in which there are provided a loading/unloading unit 701, a plated Cu film forming unit 702, a first robot 703, a third cleaning machine 704, a reversing machine 705, a reversing machine 706, a second cleaning machine 707, a second robot 708, a first cleaning machine 709, a first polishing apparatus 710, and a second polishing apparatus 711. A before-plating and after-plating film thickness measuring instrument 712 for measuring the film thicknesses before and after plating, and a dry state film thickness measuring instrument 713 for measuring the film thickness of a semiconductor substrate W in a dry state after polishing are placed near the first robot 703.

The first polishing apparatus (polishing unit) 710 has a polishing table 710-1, atop ring 710-2, atop ring head 710-3, a film thickness measuring instrument 710-4, and a pusher 710-5. The second polishing apparatus (polishing unit) 711 has a polishing table 711-1, a top ring 711-2, a top ring head 711-3, a film thickness measuring instrument 711-4, and a pusher 711-5.

A cassette 701-1 accommodating the semiconductor substrates W, in which a via hole and a trench for interconnect are formed, and a seed layer is formed thereon is placed on a loading port of the loading/unloading unit 701. The first robot 703 takes out the semiconductor substrate W from the cassette 701-1, and carries the semiconductor substrate W into the plated Cu film forming unit 702 where a plated Cu film is formed. At this time, the film thickness of the seed layer is measured with the before-plating and after-plating film thickness measuring instrument 712. The plated Cu film is formed by carrying out hydrophilic treatment of the face of the semiconductor substrate W, and then Cu plating. After formation of the plated Cu film, rinsing or cleaning of the semiconductor substrate W is carried out in the plated Cu film forming unit 702.

When the semiconductor substrate W is taken out from the plated Cu film forming unit 702 by the first robot 703, the film thickness of the plated Cu film is measured with the before-plating and after-plating film thickness measuring instrument 712. The results of its measurement are recorded into a recording device (not shown) as record data on the semiconductor substrate, and are used for judgment of an abnormality of the plated Cu film forming unit 702. After measurement of the film thickness, the first robot 703 transfers the semiconductor substrate W to the reversing machine 705, and the reversing machine 705 reverses the semiconductor substrate W (the surface on which the plated Cu film has been formed faces downward). The first polishing apparatus 710 and the second polishing apparatus 711 perform polishing in a serial mode and a parallel mode. Next, polishing in the serial mode will be described.

In the serial mode polishing, a primary polishing is performed by the polishing apparatus 710, and a secondary polishing is performed by the polishing apparatus 711. The second robot 708 picks up the semiconductor substrate W on the reversing machine 705, and places the semiconductor substrate W on the pusher 710-5 of the polishing apparatus 710. The top ring 710-2 attracts the semiconductor substrate W on the pusher 710-5 by suction, and brings the surface of the plated Cu film of the semiconductor substrate W into contact with a polishing surface of the polishing table 710-1 under pressure to perform a primary polishing. With the primary polishing, the plated Cu film is basically polished. The polishing surface of the polishing table 710-1 is composed of foamed polyurethane such as IC1000, or a material having abrasive grains fixed thereto or impregnated therein. Upon relative movements of the polishing surface and the semiconductor substrate W, the plated Cu film is polished.

After completion of polishing of the plated Cu film, the semiconductor substrate W is returned onto the pusher 710-5 by the top ring 710-2. The second robot 708 picks up the semiconductor substrate W, and introduces it into the first cleaning machine 709. At this time, a chemical liquid may be ejected toward the face and backside of the semiconductor substrate W on the pusher 710-5 to remove particles therefrom or cause particles to be difficult to adhere thereto.

After completion of cleaning in the first cleaning machine 709, the second robot 708 picks up the semiconductor substrate W, and places the semiconductor substrate W on the pusher 711-5 of the second polishing apparatus 711. The top ring 711-2 attracts the semiconductor substrate W on the pusher 711-5 by suction, and brings the surface of the semiconductor substrate W, which has the barrier layer formed thereon, into contact with a polishing surface of the polishing table 711-1 under pressure to perform the secondary polishing. The constitution of the polishing table is the same as the top ring 711-2. With this secondary polishing, the barrier layer is polished. However, there may be a case in which a Cu film and an oxide film left after the primary polishing are also polished.

A polishing surface of the polishing table 711-1 is composed of foamed polyurethane such as IC1000, or a material having abrasive grains fixed thereto or impregnated therein. Upon relative movements of the polishing surface and the semiconductor substrate W, polishing is carried out. At this time, silica, alumina, ceria, or the like is used as abrasive grains or slurry. A chemical liquid is adjusted depending on the type of the film to be polished.

Detection of an end point of the secondary polishing is performed by measuring the film thickness of the barrier layer mainly with the use of the optical film thickness measuring instrument, and detecting the film thickness which has become zero, or the surface of an insulating film comprising SiO₂ shows up. Furthermore, a film thickness measuring instrument with an image processing function is used as the film thickness measuring instrument 711-4 provided near the polishing table 711-1. By use of this measuring instrument, measurement of the oxide film is made, the results are stored as processing records of the semiconductor substrate W, and used for judging whether the semiconductor substrate W in which secondary polishing has been finished can be transferred to a subsequent step or not. If the end point of the secondary polishing is not reached, re-polishing is performed. If over-polishing has been performed beyond a prescribed value due to any abnormality, then the semiconductor substrate processing apparatus is stopped to avoid next polishing so that defective products will not increase.

After completion of the secondary polishing, the semiconductor substrate W is moved to the pusher 711-5 by the top ring 711-2. The second robot 708 picks up the semiconductor substrate W on the pusher 711-5. At this time, a chemical liquid may be ejected toward the face and backside of the semiconductor substrate W on the pusher 711-5 to remove particles therefrom or cause particles to be difficult to adhere thereto.

The second robot 708 carries the semiconductor substrate W into the second cleaning machine 707 where cleaning of the semiconductor substrate W is performed. The constitution of the second cleaning machine 707 is also the same as the constitution of the first cleaning machine 709. The face of the semiconductor substrate W is scrubbed with the PVA sponge rolls using a cleaning liquid comprising pure water to which a surface active agent, a chelating agent, or a pH regulating agent is added. A strong chemical liquid such as DHF is ejected from a nozzle toward the backside of the semiconductor substrate W to perform etching of the diffused Cu thereon. If there is no problem of diffusion, scrubbing cleaning is performed with the PVA sponge rolls using the same chemical liquid as that used for the face.

After completion of the above cleaning, the second robot 708 picks up the semiconductor substrate W and transfers it to the reversing machine 706, and the reversing machine 706 reverses the semiconductor substrate W. The semiconductor substrate W which has been reversed is picked up by the first robot 703, and transferred to the third cleaning machine 704. In the third cleaning machine 704, megasonic water excited by ultrasonic vibrations is ejected toward the face of the semiconductor substrate W to clean the semiconductor substrate W. At this time, the face of the semiconductor substrate W may be cleaned with a known pencil type sponge using a cleaning liquid comprising pure water to which a surface active agent, a chelating agent, or a pH regulating agent is added. Thereafter, the semiconductor substrate W is dried by spin-drying.

As described above, if the film thickness has been measured with the film thickness measuring instrument 711-4 provided near the polishing table 711-1, then the semiconductor substrate W is not subjected to further process and is accommodated into the cassette placed on the unloading port of the loading/unloading unit 701.

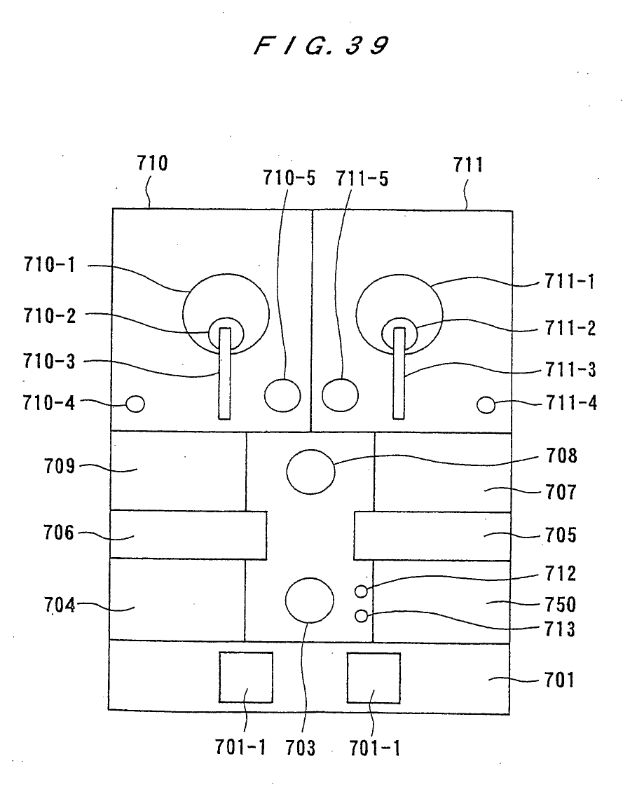

FIG. 39 is a view showing the plan constitution of another example of a semiconductor substrate processing apparatus. The substrate processing apparatus differs from the substrate processing apparatus shown in FIG. 38 in that a cap plating unit 750 is provided instead of the plated Cu film forming unit 702 in FIG. 38.

A cassette 701-1 accommodating the semiconductor substrates W formed plated Cu film is placed on a load port of a loading/unloading unit 701. The semiconductor substrate W taken out from the cassette 701-1 is transferred to the first polishing apparatus 710 or second polishing apparatus 711 in which the surface of the plated Cu film is polished. After completion of polishing of the plated Cu film, the semiconductor substrate W is cleaned in the first cleaning machine 709.

After completion of cleaning in the first cleaning machine 709, the semiconductor substrate W is transferred to the cap plating unit 750 where cap plating is applied onto the surface of the plated Cu film with the aim of preventing oxidation of plated Cu film due to the atmosphere. The semiconductor substrate to which cap plating has been applied is carried by the second robot 708 from the cap plating unit 750 to the second cleaning machine 707 where it is cleaned with pure water or deionized water. The semiconductor substrate after completion of cleaning is returned into the cassette 701-1 placed on the loading/unloading unit 701.

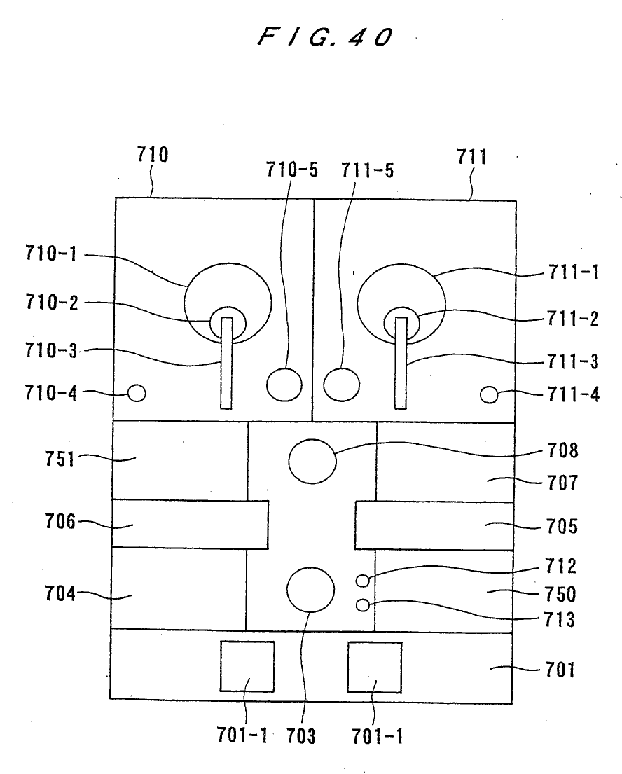

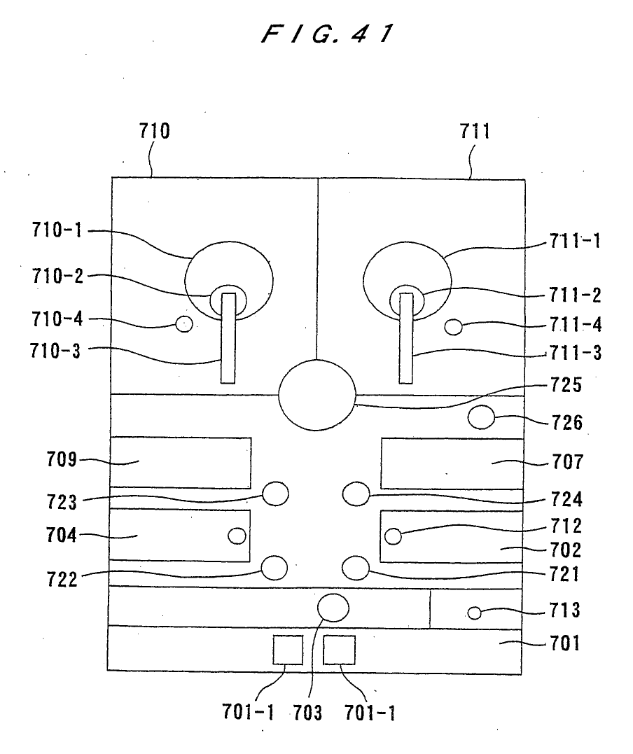

FIG. 40 is a view showing the plan constitution of still another example of a semiconductor substrate processing apparatus. The substrate processing apparatus differs from the substrate processing apparatus shown in FIG. 39 in that an annealing unit 751 is provided instead of the first cleaning machine 709 in FIG. 39.

The semiconductor substrate W, which is polished in the polishing unit 710 or 711, and cleaned in the second cleaning machine 707 described above, is transferred to the cap plating unit 750 where cap plating is applied onto the surface of the plated Cu film. The semiconductor substrate to which cap plating has been applied is carried by the second robot 708 from the cap plating unit 750 to the second cleaning machine 707 where it is cleaned.

After completion of cleaning in the second cleaning machine 707, the semiconductor substrate W is transferred to the annealing unit 751 in which the substrate is annealed, whereby the plated Cu film is alloyed so as to increase the electromigration resistance of the plated Cu film. The semiconductor substrate W to which annealing treatment has been applied is carried from the annealing unit 751 to the second cleaning machine 707 where it is cleaned with pure water or deionized water. The semiconductor substrate W after completion of cleaning is returned into the cassette 701-1 placed on the loading/unloading unit 701.

FIG. 41 is a view showing a plan layout constitution of another example of the substrate processing apparatus. In FIG. 41, portions denoted by the same reference numerals as those in FIG. 38 show the same or corresponding portions. In the substrate processing apparatus, a pusher indexer 725 is disposed close to a first polishing apparatus 710 and a second polishing apparatus 711. Substrate placing tables 721, 722 are disposed close to a third cleaning machine 704 and a plated Cu film forming unit 702, respectively. A robot 723 is disposed close to a first cleaning machine 709 and the third cleaning machine 704. Further, a robot 724 is disposed close to a second cleaning machine 707 and the plated Cu film forming unit 702, and a dry state film thickness measuring instrument 713 is disposed close to a loading/unloading unit 701 and a first robot 703.

In the substrate processing apparatus of the above constitution, the first robot 703 takes out a semiconductor substrate W from a cassette 701-1 placed on the load port of the loading/unloading unit 701. After the film thicknesses of a barrier layer and a seed layer are measured with the dry state film thickness measuring instrument 713, the first robot 703 places the semiconductor substrate W on the substrate placing table 721. In the case where the dry state film thickness measuring instrument 713 is provided on the hand of the first robot 703, the film thicknesses are measured thereon, and the substrate is placed on the substrate placing table 721. The second robot 723 transfers the semiconductor substrate W on the substrate placing table 721 to the plated Cu film forming unit 702 in which a plated Cu film is formed. After formation of the plated Cu film, the film thickness of the plated Cu film is measured with a before-plating and after-plating film thickness measuring instrument 712. Then, the second robot 723 transfers the semiconductor substrate W to the pusher indexer 725 and loads it thereon.

[Serial Mode]

In the serial mode, a top ring 710-2 holds the semiconductor substrate W on the pusher indexer 725 by suction, transfers it to a polishing table 710-1, and presses the semiconductor substrate W against a polishing surface on the polishing table 710-1 to perform polishing. Detection of the end point of polishing is performed by the same method as described above. The semiconductor substrate W after completion of polishing is transferred to the pusher indexer 725 by the top ring 710-2, and loaded thereon. The second robot 723 takes out the semiconductor substrate W, and carries it into the first cleaning machine 709 for cleaning. Then, the semiconductor substrate W is transferred to the pusher indexer 725, and loaded thereon.

A top ring 711-2 holds the semiconductor substrate W on the pusher indexer 725 by suction, transfers it to a polishing table 711-1, and presses the semiconductor substrate W against a polishing surface on the polishing table 711-1 to perform polishing. Detection of the end point of polishing is performed by the same method as described above. The semiconductor substrate W after completion of polishing is transferred to the pusher indexer 725 by the top ring 711-2, and loaded thereon. The third robot 724 picks up the semiconductor substrate W, and its film thickness is measured with a film thickness measuring instrument 726. Then, the semiconductor substrate W is carried into the second cleaning machine 707 for cleaning. Thereafter, the semiconductor substrate W is carried into the third cleaning machine 704, where it is cleaned and then dried by spin-drying. Then, the semiconductor substrate W is picked up by the third robot 724, and placed on the substrate placing table 722.

[Parallel Mode]

In the parallel mode, the top ring 710-2 or 711-2 holds the semiconductor substrate W on the pusher indexer 725 by suction, transfers it to the polishing table 710-1 or 711-1, and presses the semiconductor substrate W against the polishing surface on the polishing table 710-1 or 711-1 to perform polishing. After measurement of the film thickness, the third robot 724 picks up the semiconductor substrate W, and places it on the substrate placing table 722.

The first robot 703 transfers the semiconductor substrate W on the substrate placing table 722 to the dry state film thickness measuring instrument 713. After the film thickness is measured, the semiconductor substrate W is returned to the cassette 701-1 of the loading/unloading unit 701.

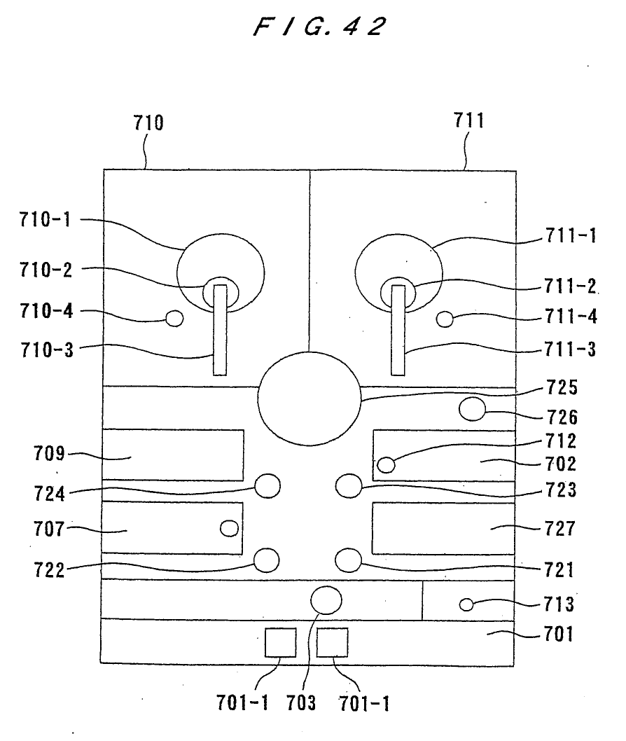

FIG. 42 is a view showing another plan layout constitution of the substrate processing apparatus. The substrate processing apparatus is such a substrate processing apparatus which forms a seed layer and a plated Cu film on a semiconductor substrate W having no seed layer formed thereon, and polishes these films to form interconnects.

In the substrate polishing apparatus, a pusher indexer 725 is disposed close to a first polishing apparatus 710 and a second polishing apparatus 711, substrate placing tables 721, 722 are disposed close to a second cleaning machine 707 and a seed layer forming unit 727, respectively, and a robot 723 is disposed close to the seed layer forming unit 727 and a plated Cu film forming unit 702. Further, a robot 724 is disposed close to a first cleaning machine 709 and the second cleaning machine 707, and a dry state film thickness measuring instrument 713 is disposed close to a loading/unloading unit 701 and a first robot 703.

The first robot 703 takes out a semiconductor substrate W having a barrier layer thereon from a cassette 701-1 placed on the load port of the loading/unloading unit 701, and places it on the substrate placing table 721. Then, the second robot 723 transfers the semiconductor substrate W to the seed layer forming unit 727 where a seed layer is formed. The seed layer is formed by electroless plating. The second robot 723 enables the semiconductor substrate having the seed layer formed thereon to be measured in thickness of the seed layer by the before-plating and after-plating film thickness measuring instrument 712. After measurement of the film thickness, the semiconductor substrate is carried into the plated Cu film forming unit 702 where a plated Cu film is formed.

After formation of the plated Cu film, its film thickness is measured, and the semiconductor substrate is transferred to a pusher indexer 725. A top ring 710-2 or 711-2 holds the semiconductor substrate W on the pusher indexer 725 by suction, and transfers it to a polishing table 710-1 or 711-1 to perform polishing. After polishing, the top ring 710-2 or 711-2 transfers the semiconductor substrate W to a film thickness measuring instrument 710-4 or 711-4 to measure the film thickness. Then, the top ring 710-2 or 711-2 transfers the semiconductor substrate W to the pusher indexer 725, and places it thereon.

Then, the third robot 724 picks up the semiconductor substrate W from the pusher indexer 725, and carries it into the first cleaning machine 709. The third robot 724 picks up the cleaned semiconductor substrate W from the first cleaning machine 709, carries it into the second cleaning machine 707, and places the cleaned and dried semiconductor substrate on the substrate placing table 722. Then, the first robot 703 picks up the semiconductor substrate W, and transfers it to the dry state film thickness measuring instrument 713 in which the film thickness is measured, and the first robot 703 carries it into the cassette 701-1 placed on the unload port of the loading/unloading unit 701.

In the substrate processing apparatus shown in FIG. 42, interconnects are formed by forming a barrier layer, a seed layer and a plated Cu film on a semiconductor substrate W having a via hole or a trench of a circuit pattern formed therein, and polishing them.

The cassette 701-1 accommodating the semiconductor substrates W before formation of the barrier layer is placed on the load port of the loading/unloading unit 701. The first robot 703 takes out the semiconductor substrate W from the cassette 701-1 placed on the load port of the loading/unloading unit 701, and places it on the substrate placing table 721. Then, the second robot 723 transfers the semiconductor substrate W to the seed layer forming unit 727 where a barrier layer and a seed layer are formed. The barrier layer and the seed layer are formed by electroless plating. The second robot 723 brings the semiconductor substrate W having the barrier layer and the seed layer formed thereon to the before-plating and after-plating film thickness measuring instrument 712 which measures the film thicknesses of the barrier layer and the seed layer. After measurement of the film thicknesses, the semiconductor substrate W is carried into the plated Cu film forming unit 702 where a plated Cu film is formed.

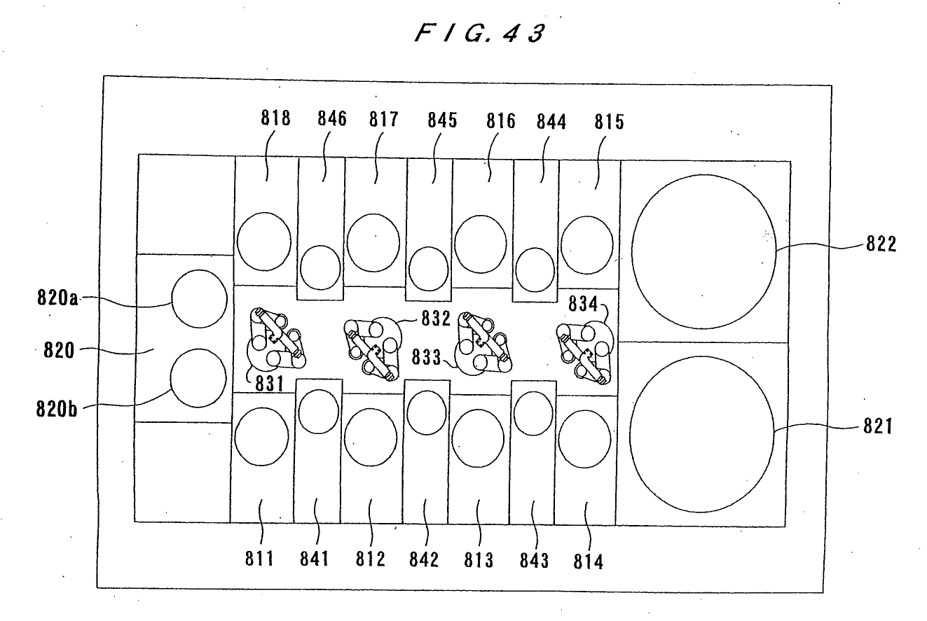

FIG. 43 is a view showing plan layout constitution of another example of the substrate processing apparatus. In the substrate processing apparatus, there are provided a barrier layer forming unit 811, a seed layer forming unit 812, a plated film forming unit 813, an annealing unit 814, a first cleaning unit 815, a bevel and backside cleaning unit 816, a cap plating unit 817, a second cleaning unit 818, a first aligner and film thickness measuring instrument 841, a second aligner and film thickness measuring instrument 842, a first substrate reversing machine 843, a second substrate reversing machine 844, a substrate temporary placing table 845, a third film thickness measuring instrument 846, a loading/unloading unit 820, a first polishing apparatus 821, a second polishing apparatus 822, a first robot 831, a second robot 832, a third robot 833, and a fourth robot 834. The film thickness measuring instruments 841, 842, and 846 are units, have the same size as the frontage dimension of other units (plating, cleaning, annealing units, and the like), and are thus interchangeable.

In this example, an electroless Ru plating apparatus can be used as the barrier layer forming unit 811, an electroless Cu plating apparatus as the seed layer forming unit 812, and an electroplating apparatus as the plated film forming unit 813.

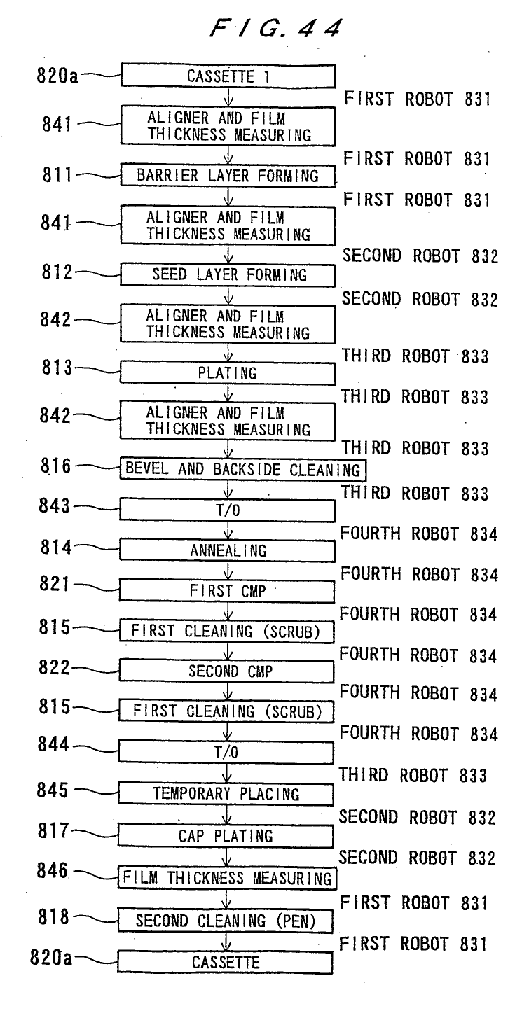

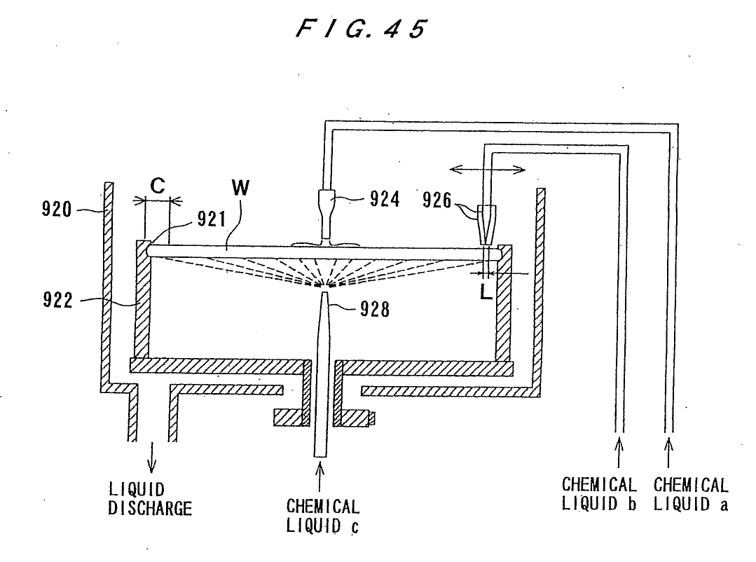

FIG. 44 is a flow chart showing the flow of the respective steps in the present substrate processing apparatus. The respective steps in the apparatus will be described according to this flow chart. First, a semiconductor substrate taken out by the first robot 831 from a cassette 820a placed on the load and unload unit 820 is placed in the first aligner and film thickness measuring instrument 841, in such a state that its surface, to be plated, faces upward. In order to set a reference point for a position at which film thickness measurement is made, notch alignment for film thickness measurement is performed, and then film thickness data on the semiconductor substrate before formation of a Cu film are obtained.

Then, the semiconductor substrate is transferred to the barrier layer forming unit 811 by the first robot 831. The barrier layer forming unit 811 is such an apparatus for forming a barrier layer on the semiconductor substrate by electroless Ru plating, and the barrier layer forming unit 811 forms an Ru film as a film for preventing Cu from diffusing into an interlayer insulator film (e.g. SiO₂) of a semiconductor device.

The semiconductor substrate discharged after cleaning and drying steps is transferred by the first robot 831 to the first aligner and film thickness measuring instrument 841, where the film thickness of the semiconductor substrate, i.e., the film thickness of the barrier layer is measured.

The semiconductor substrate after film thickness measurement is carried into the seed layer forming unit 812 by the second robot 832, and a seed layer is formed on the barrier layer by electroless Cu plating. The semiconductor substrate discharged after cleaning and drying steps is transferred by the second robot 832 to the second aligner and film thickness measuring instrument 842 for determination of a notch position, before the semiconductor substrate is transferred to the plated film forming unit 813, which is an impregnation plating unit, and then notch alignment for Cu plating is performed by the film thickness measuring instrument 842. If necessary, the film thickness of the semiconductor substrate before formation of a Cu film may be measured again in the film thickness measuring instrument 842.

The semiconductor substrate which has completed notch alignment is transferred by the third robot 833 to the plated film forming unit 813 where Cu plating is applied to the semiconductor substrate. The semiconductor substrate discharged after cleaning and drying steps is transferred by the third robot 833 to the bevel and backside cleaning unit 816 where an unnecessary Cu film (seed layer) at a peripheral portion of the semiconductor substrate is removed. In the bevel and backside cleaning unit 816, the bevel is etched in a preset time, and Cu adhering to the backside of the semiconductor substrate is cleaned with a chemical liquid such as hydrofluoric acid. At this time, before transferring the semiconductor substrate to the bevel and backside cleaning unit 816, film thickness measurement of the semiconductor substrate may be made by the second aligner and film thickness measuring instrument 842 to obtain the thickness value of the Cu film formed by plating, and based on the obtained results, the bevel etching time may be changed arbitrarily to carry out etching. The region etched by bevel etching is a region which corresponds to a peripheral edge portion of the substrate and has no circuit formed therein, or a region which is not utilized finally as a chip although a circuit is formed. A bevel portion is included in this region.

The semiconductor substrate discharged after cleaning and drying steps in the bevel and backside cleaning unit 816 is transferred by the third robot 833 to the substrate reversing machine 843. After the semiconductor substrate is turned over by the substrate reversing machine 843 to cause the plated surface to be directed downward, the semiconductor substrate is introduced into the annealing unit 814 by the fourth robot 834 for thereby stabilizing an interconnection portion. Before and/or after annealing treatment, the semiconductor substrate is carried into the second aligner and film thickness measuring instrument 842 where the film thickness of a copper film formed on the semiconductor substrate is measured. Then, the semiconductor substrate is carried by the fourth robot 834 into the first polishing apparatus 821 in which the Cu film and the seed layer of the semiconductor substrate are polished.

At this time, desired abrasive grains or the like are used, but fixed abrasive may be used in order to prevent dishing and enhance flatness of the face. After completion of primary polishing, the semiconductor substrate is transferred by the fourth robot 834 to the first cleaning unit 815 where it is cleaned. This cleaning is scrub-cleaning in which rolls having substantially the same length as the diameter of the semiconductor substrate are placed on the face and the backside of the semiconductor substrate, and the semiconductor substrate and the rolls are rotated, while pure water or deionized water is flowed, thereby performing cleaning of the semiconductor substrate.

After completion of the primary cleaning, the semiconductor substrate is transferred by the fourth robot 834 to the second polishing apparatus 822 where the barrier layer on the semiconductor substrate is polished. At this time, desired abrasive grains or the like are used, but fixed abrasive may be used in order to prevent dishing and enhance flatness of the face. After completion of secondary polishing, the semiconductor substrate is transferred by the fourth robot 834 again to the first cleaning unit 815 where scrub-cleaning is performed. After completion of cleaning, the semiconductor substrate is transferred by the fourth robot 834 to the second substrate reversing machine 844 where the semiconductor substrate is reversed to cause the plated surface to be directed upward, and then the semiconductor substrate is placed on the substrate temporary placing table 845 by the third robot.

The semiconductor substrate is transferred by the second robot 832 from the substrate temporary placing table 845 to the cap plating unit 817 where cap plating is applied onto the Cu surface with the aim of preventing oxidation of Cu due to the atmosphere. The semiconductor substrate to which cap plating has been applied is carried by the second robot 832 from the cap plating unit 817 to the third film thickness measuring instrument 846 where the thickness of the copper film is measured. Thereafter, the semiconductor substrate is carried by the first robot 831 into the second cleaning unit 818 where it is cleaned with pure water or deionized water. The semiconductor substrate after completion of cleaning is returned into the cassette 820a placed on the loading/unloading unit 820.

The aligner and film thickness measuring instrument 841 and the aligner and film thickness measuring instrument 842 perform positioning of the notch portion of the substrate and measurement of the film thickness.

The seed layer forming unit 812 may be omitted. In this case, a plated film may be formed on a barrier layer directly in a plated film forming unit 813.

The bevel and backside cleaning unit 816 can perform an edge (bevel) Cu etching and a backside cleaning at the same time, and can suppress growth of a natural oxide film of copper at the circuit formation portion on the surface of the substrate. FIG. 45 shows a schematic view of the bevel and backside cleaning unit 816. As shown in FIG. 45, the bevel and backside cleaning unit 816 has a substrate holding portion 922 positioned inside a bottomed cylindrical waterproof cover 920 and adapted to rotate a substrate W at a high speed, in such a state that the face of the substrate W faces upwardly, while holding the substrate W horizontally by spin chucks 921 at a plurality of locations along a circumferential direction of a peripheral edge portion of the substrate, a center nozzle 924 placed above a nearly central portion of the face of the substrate W held by the substrate holding portion 922, and an edge nozzle 926 placed above the peripheral edge portion of the substrate W. The center nozzle 924 and the edge nozzle 926 are directed downward. A back nozzle 928 is positioned below a nearly central portion of the backside of the substrate W, and directed upward. The edge nozzle 926 is adapted to be movable in a diametrical direction and a height direction of the substrate W.

The width of movement L of the edge nozzle 926 is set such that the edge nozzle 926 can be arbitrarily positioned in a direction toward the center from the outer peripheral end surface of the substrate, and a set value for L is inputted according to the size, usage, or the like of the substrate W. Normally, an edge cut width C is set in the range of 2 mm to 5 mm. In the case where a rotational speed of the substrate is a certain value or higher at which the amount of liquid migration from the backside to the face is not problematic, the copper film within the edge cut width C can be removed.

Next, the method of cleaning with this cleaning apparatus will be described. First, the semiconductor substrate W is horizontally rotated integrally with the substrate holding portion 922, with the substrate being held horizontally by the spin chucks 921 of the substrate holding portion 922. In this state, an acid solution is supplied from the center nozzle 924 to the central portion of the face of the substrate W. The acid solution may be a non-oxidizing acid, and hydrofluoric acid, hydrochloric acid, sulfuric acid, citric acid, oxalic acid, or the like is used. On the other hand, an oxidizing agent solution is supplied continuously or intermittently from the edge nozzle 926 to the peripheral edge portion of the substrate W. As the oxidizing agent solution, one of an aqueous solution of ozone, an aqueous solution of hydrogen peroxide, an aqueous solution of nitric acid, and an aqueous solution of sodium hypochlorite is used, or a combination of these is used.

In this manner, the copper film, or the like formed on the upper surface and end surface in the region of the peripheral edge portion C of the semiconductor substrate W is rapidly oxidized with the oxidizing agent solution, and is simultaneously etched with the acid solution supplied from the center nozzle 924 and spread on the entire face of the substrate, whereby it is dissolved and removed. By mixing the acid solution and the oxidizing agent solution at the peripheral edge portion of the substrate, a steep etching profile can be obtained, in comparison with a mixture of them which is produced in advance being supplied. At this time, the copper etching rate is determined by their concentrations. If a natural oxide film of copper is formed in the circuit-formed portion on the face of the substrate, this natural oxide is immediately removed by the acid solution spreading on the entire face of the substrate according to rotation of the substrate, and does not grow any more. After the supply of the acid solution from the center nozzle 924 is stopped, the supply of the oxidizing agent solution from the edge nozzle 926 is stopped. As a result, silicon exposed on the surface is oxidized, and deposition of copper can be suppressed.

On the other hand, an oxidizing agent solution and a silicon oxide film etching agent are supplied simultaneously or alternately from the back nozzle 928 to the central portion of the backside of the substrate. Therefore, copper or the like adhering in a metal form to the backside of the semiconductor substrate W can be oxidized with the oxidizing agent solution, together with silicon of the substrate, and can be etched and removed with the silicon oxide film etching agent. This oxidizing agent solution is preferably the same as the oxidizing agent solution supplied to the face, because the types of chemicals are decreased in number. Hydrofluoric acid can be used as the silicon oxide film etching agent, and if hydrofluoric acid is used as the acid solution on the face of the substrate, the types of chemicals can be decreased in number. Thus, if the supply of the oxidizing agent is stopped first, a hydrophobic surface is obtained. If the etching agent solution is stopped first, a water-saturated surface (a hydrophilic surface) is obtained, and thus the backside surface can be adjusted to a condition which will satisfy the requirements of a subsequent process.

In this manner, the acid solution, i.e., etching solution is supplied to the substrate to remove metal ions remaining on the surface of the substrate W. Then, pure water is supplied to replace the etching solution with pure water and remove the etching solution, and then the substrate is dried by spin-drying. In this way, removal of the copper film in the edge cut width C at the peripheral edge portion on the face of the semiconductor substrate, and removal of copper contaminants on the backside are performed simultaneously to thus allow this treatment to be completed, for example, within 80 seconds. The etching cut width of the edge can be set arbitrarily (from 2 to 5 mm), but the time required for etching does not depend on the cut width.

Annealing treatment performed before the CMP process and after plating has a favorable effect on the subsequent CMP treatment and on the electrical characteristics of interconnection. Observation of the surface of broad interconnection (unit of several micrometers) after the CMP treatment without annealing showed many defects such as microvoids, which resulted in an increase in the electrical resistance of the entire interconnection. Execution of annealing ameliorated the increase in the electrical resistance. In the presence of annealing, thin interconnection showed no voids. Thus, the degree of grain growth is presumed to be involved in these phenomena. That is, the following mechanism can be speculated: Grain growth is difficult to occur in thin interconnection. In broad interconnection, on the other hand, grain growth proceeds in accordance with annealing treatment. During the process of grain growth, ultra-fine pores in the plated film, which are too small to be seen by the SEM (scanning electron microscope), gather and move upward, thus forming microvoid-like depressions in the upper part of the interconnection. The annealing conditions in the annealing unit 814 are such that hydrogen (2% or less) is added in a gas atmosphere, the temperature is in the range of 300° C. to 400° C., and the time is in the range of 1 to 5 minutes. Under these conditions, the above effects were obtained.

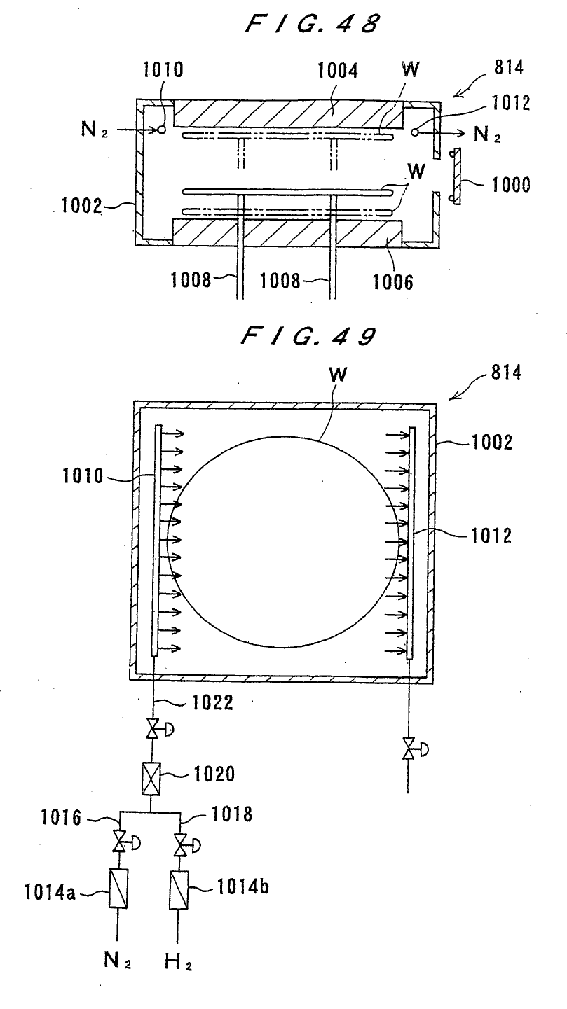

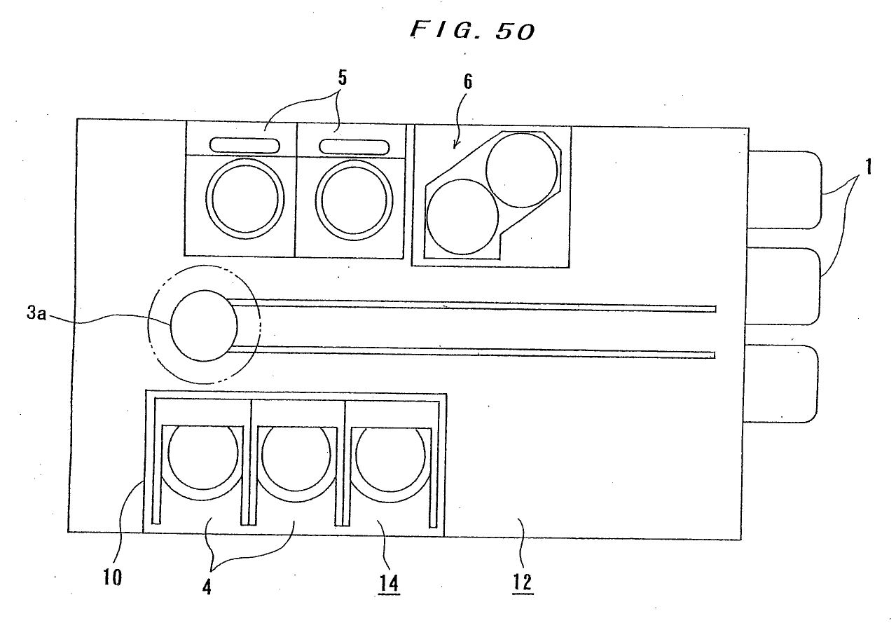

FIGS. 48 and 49 show the annealing unit 814. The annealing unit 814 comprises a chamber 1002 having a gate 1000 for taking in and taking out the semiconductor substrate W, a hot plate 1004 disposed at an upper position in the chamber 1002 for heating the semiconductor substrate W to e.g. 400° C., and a cool plate 1006 disposed at a lower position in the chamber 1002 for cooling the semiconductor substrate W by, for example, flowing cooling water inside the plate. The annealing unit 814 also has a plurality of vertically movable elevating pins 1008 penetrating the cool plate 1006 and extending upward and downward therethrough for placing and holding the semiconductor substrate W on them. The annealing unit further includes a gas introduction pipe 1010 for introducing an antioxidant gas between the semiconductor substrate W and the hot plate 1004 during annealing, and a gas discharge pipe 1012 for discharging the gas which has been introduced from the gas introduction pipe 1010 and flowed between the semiconductor substrate W and the hot plate 1004. The pipes 1010 and 1012 are disposed on the opposite sides of the hot plate 1004.

The gas introduction pipe 1010 is connected to a mixed gas introduction line 1022 which in turn is connected to a mixer 1020 where a N₂ gas introduced through a N₂ gas introduction line 1016 containing a filter 1014a, and a H₂ gas introduced through a H₂ gas introduction line 1018 containing a filter 1014b, are mixed to form a mixed gas which flows through the line 1022 into the gas introduction pipe 1010.

In operation, the semiconductor substrate W, which has been carried in the chamber 1002 through the gate 1000, is held on the elevating pins 1008 and the elevating pins 1008 are raised up to a position at which the distance between the semiconductor substrate W held on the lifting pins 1008 and the hot plate 1004 becomes e.g. 0.1-1.0 mm. In this state, the semiconductor substrate W is then heated to e.g. 400° C. through the hot plate 1004 and, at the same time, the antioxidant gas is introduced from the gas introduction pipe 1010 and the gas is allowed to flow between the semiconductor substrate W and the hot plate 1004 while the gas is discharged from the gas discharge pipe 1012, thereby annealing the semiconductor substrate W while preventing its oxidation. The annealing treatment may be completed in about several tens of seconds to 60 seconds. The heating temperature of the substrate may be selected in the range of 100-600° C.

After the completion of the annealing, the elevating pins 1008 are lowered down to a position at which the distance between the semiconductor substrate W held on the elevating pins 1008 and the cool plate 1006 becomes e.g. 0-0.5 mm. In this state, by introducing cooling water into the cool plate 1006, the semiconductor substrate W is cooled by the cool plate to a temperature of 100° C. or lower in e.g. 10-60 seconds. The cooled semiconductor substrate is sent to the next step.

A mixed gas of N₂ gas with several percentages of H₂ gas is used as the above antioxidant gas. However, N₂ gas may be used singly.

The annealing unit may be placed in the electroplating apparatus.

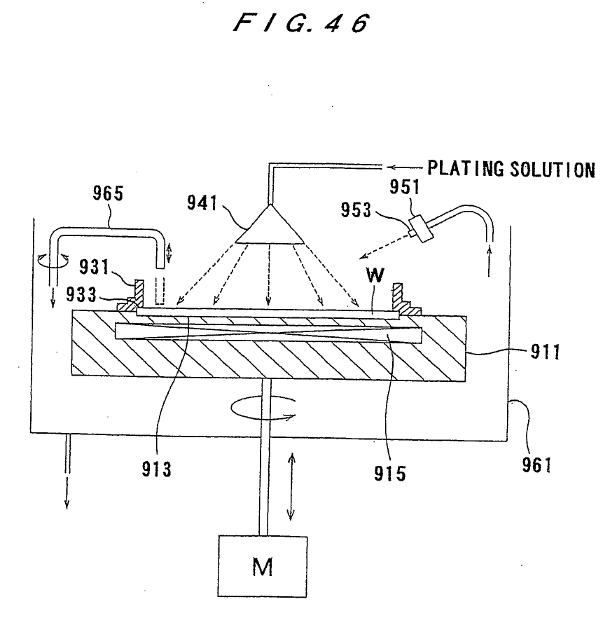

FIG. 46 is a schematic constitution drawing of the electroless plating apparatus. As shown in FIG. 46, this electroless plating apparatus comprises holding means 911 for holding a semiconductor substrate W to be plated on its upper surface, a dam member 931 for contacting a peripheral edge portion of a surface to be plated (upper surface) of the semiconductor substrate W held by the holding means 911 to seal the peripheral edge portion, and a shower head 941 for supplying a plating solution to the surface, to be plated, of the semiconductor substrate W having the peripheral edge portion sealed with the dam member 931. The electroless plating apparatus further comprises cleaning liquid supply means 951 disposed near an upper outer periphery of the holding means 911 for supplying a cleaning liquid to the surface, to be plated, of the semiconductor substrate W, a recovery vessel 961 for recovering a cleaning liquid or the like (plating waste liquid) discharged, a plating solution recovery nozzle 965 for sucking in and recovering the plating solution held on the semiconductor substrate W, and a motor M for rotationally driving the holding means 911. The respective members will be described below.

The holding means 911 has a substrate placing portion 913 on its upper surface for placing and holding the semiconductor substrate W. The substrate placing portion 913 is adapted to place and fix the semiconductor substrate W. Specifically, the substrate placing portion 913 has a vacuum attracting mechanism (not shown) for attracting the semiconductor substrate W to a backside thereof by vacuum suction. A backside heater 915, which is planar and heats the surface, to be plated, of the semiconductor substrate W from underside to keep it warm, is installed on the backside of the substrate placing portion 913. The backside heater 915 is composed of, for example, a rubber heater. This holding means 911 is adapted to be rotated by the motor M and is movable vertically by raising and lowering means (not shown).

The dam member 931 is tubular, has a seal portion 933 provided in a lower portion thereof for sealing the outer peripheral edge of the semiconductor substrate W, and is installed so as not to move vertically from the illustrated position.

The shower head 941 is of a structure having many nozzles provided at the front end for scattering the supplied plating solution in a shower form and supplying it substantially uniformly to the surface, to be plated, of the semiconductor substrate W. The cleaning liquid supply means 951 has a structure for ejecting a cleaning liquid from a nozzle 953.

The plating solution recovery nozzle 965 is adapted to be movable upward and downward and swingable, and the front end of the plating solution recovery nozzle 965 is adapted to be lowered inwardly of the dam member 931 located on the upper surface peripheral edge portion of the semiconductor substrate W and to suck in the plating solution on the semiconductor substrate W.

Next, the operation of the electroless plating apparatus will be described. First, the holding means 911 is lowered from the illustrated state to provide a gap of a predetermined dimension between the holding means 911 and the dam member 931, and the semiconductor substrate W is placed on and fixed to the substrate placing portion 913. An 8 inch substrate, for example, is used as the semiconductor substrate W.

Then, the holding means 911 is raised to bring its upper surface into contact with the lower surface of the dam member 931 as illustrated, and the outer periphery of the semiconductor substrate W is sealed with the seal portion 933 of the dam member 931. At this time, the surface of the semiconductor substrate W is in an open state.

Then, the semiconductor substrate W itself is directly heated by the backside heater 915 to render the temperature of the semiconductor substrate W, for example, 70° C. (maintained until termination of plating). Then, the plating solution heated, for example, to 50° C. is ejected from the shower head 941 to pour the plating solution over substantially the entire surface of the semiconductor substrate W. Since the surface of the semiconductor substrate W is surrounded by the dame member 931, the poured plating solution is all held on the surface of the semiconductor substrate W. The amount of the supplied plating solution may be a small amount which will become a 1 mm thickness (about 30 ml) on the surface of the semiconductor substrate W. The depth of the plating solution held on the surface to be plated may be 10 mm or less, and may be even 1 mm as in this embodiment. If a small amount of the supplied plating solution is sufficient, the heating apparatus for heating the plating solution may be of a small size. In this example, the temperature of the semiconductor substrate W is raised to 70° C., and the temperature of the plating solution is raised to 50° C. by heating. Thus, the surface, to be plated, of the semiconductor substrate W becomes, for example, 60° C., and hence a temperature optimal for a plating reaction in this example can be achieved.

The semiconductor substrate W is instantaneously rotated by the motor M to perform uniform liquid wetting of the surface to be plated, and then plating of the surface to be plated is performed in such a state that the semiconductor substrate W is in a stationary state. Specifically, the semiconductor substrate W is rotated at 100 rpm or less for only 1 second to uniformly wet the surface, to be plated, of the semiconductor substrate W with the plating solution. Then, the semiconductor substrate W is kept stationary, and electroless plating is performed for 1 minute. The instantaneous rotating time is 10 seconds or less at the longest.

After completion of the plating treatment, the front end of the plating solution recovery nozzle 965 is lowered to an area near the inside of the dam member 931 on the peripheral edge portion of the semiconductor substrate W to suck in the plating solution. At this time, if the semiconductor substrate W is rotated at a rotational speed of, for example, 100 rpm or less, the plating solution remaining on the semiconductor substrate W can be gathered in the portion of the dam member 931 on the peripheral edge portion of the semiconductor substrate W under centrifugal force, so that recovery of the plating solution can be performed with a good efficiency and a high recovery rate. The holding means 911 is lowered to separate the semiconductor substrate W from the dam member 931. The semiconductor substrate W is started to be rotated, and the cleaning liquid (ultra-pure water) is jetted at the plated surface of the semiconductor substrate W from the nozzle 953 of the cleaning liquid supply means 951 to cool the plated surface, and simultaneously perform dilution and cleaning, thereby stopping the electroless plating reaction. At this time, the cleaning liquid jetted from the nozzle 953 may be supplied to the dam member 931 to perform cleaning of the dam member 931 at the same time. The plating waste liquid at this time is recovered into the recovery vessel 961 and discarded.

Then, the semiconductor substrate W is rotated at a high speed by the motor M for spin-drying, and then the semiconductor substrate W is removed from the holding means 911.

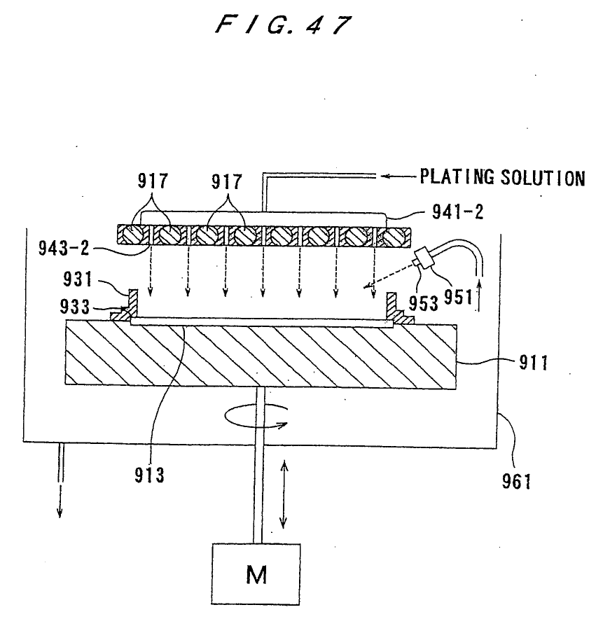

FIG. 47 is a schematic constitution drawing of another electroless plating apparatus. The electroless plating apparatus of FIG. 47 is different from the electroless plating apparatus of FIG. 46 in that instead of providing the backside heater 915 in the holding means 911, lamp heaters 917 are disposed above the holding means 911, and the, lamp heaters 917 and a shower head 941-2 are integrated. For example, a plurality of ring-shaped lamp heaters 917 having different radii are provided concentrically, and many nozzles 943-2 of the shower head 941-2 are open in a ring form from the gaps between the lamp heaters 917. The lamp heaters 917 may be composed of a single spiral lamp heater, or may be composed of other lamp heaters of various structures and arrangements.

Even with this constitution, the plating solution can be supplied from each nozzle 943-2 to the surface, to be plated, of the semiconductor substrate W substantially uniformly in a shower form. Further, heating and heat retention of the semiconductor substrate W can be performed by the lamp heaters 917 directly uniformly. The lamp heaters 917 heat not only the semiconductor substrate W and the plating solution, but also ambient air, thus exhibiting a heat retention effect on the semiconductor substrate W.

Direct heating of the semiconductor substrate W by the lamp heaters 917 requires the lamp heaters 917 with a relatively large electric power consumption. In place of such lamp heaters 917, lamp heaters 917 with a relatively small electric power consumption and the backside heater 915 shown in FIG. 45 may be used in combination to heat the semiconductor substrate W mainly with the backside heater 915 and to perform heat retention of the plating solution and ambient air mainly by the lamp heaters 917. In the same manner as in the aforementioned embodiment, means for directly or indirectly cooling the semiconductor substrate W may be provided to perform temperature control.

The cap plating described above is preferably performed by electroless plating process, but may be performed by electroplating process.

FIG. 50 is a plan view showing an overall arrangement of a [symbol] ting apparatus according to another embodiment of the [symbol] invention. The plating apparatus shown in FIG. 50 [symbol] from the plating apparatus shown in FIG. 2 in that the [symbol] ing/unloading section 11 and the temporary holding stage [symbol] 7 are not provided in the apparatus and a single substrate transfer device 3a is provided in the processing section 12.

Specifically, the first robot 2 and the second robot 3 are incorporated into the single substrate transfer device 3a so that the processing section 12 includes the loading/unloading section. In this case, the single substrate transfer device 3a serves to transfer a substrate between cassettes placed on the loading/unloading units 1, the plating units 4, the bevel and backside cleaning units 5, and the annealing unit 6. Other structures and arrangements in the present embodiment is the same as those of the first embodiment.

Although certain preferred embodiments of the present invention have been shown and described in detail, it should be understood that various changes and modifications may be made therein without departing from the scope of the appended claims.

### INDUSTRIAL APPLICABILITY

The present invention is suitable for use in a plating apparatus for filling interconnection grooves formed in a semiconductor substrate with metal such as copper.

1. A plating apparatus for plating a substrate, comprising:
a loading/unloading section having a loading/unloading unit for loading and unloading substrates, and a first substrate transfer device for transferring the substrate from said loading/unloading unit;
a processing section having at least one processing unit for processing the substrate, a plating section having at least one plating unit for plating the substrate, and a second substrate transfer device for transferring the substrate to said plating unit;
a first air supplying system for supplying air into said processing section; and
a second air supplying system for supplying air into said plating section independently of said first air supplying system,
wherein said processing unit comprises a substrate holder for holding the substrate,
wherein said plating unit comprises a plating container for holding a plating solution therein, and
wherein said second transfer device transfers the substrate between said first substrate transfer device, said processing unit, and said plating unit.

2. (Cancelled)

3. (Cancelled)

4. (Cancelled)

5. A plating apparatus according to claim 1, wherein said first air supplying system has a fan for supplying air into said processing section.

6. A plating apparatus according to claim 1, wherein said first air supplying system has a circulation pipe for circulating the air in said processing section.

7. A plating apparatus according to claim 1, wherein said second air supplying system has a fan for supplying air into said plating section.

8. A plating apparatus according to claim 1, wherein said second air supplying system has a circulation pipe for circulating the air in said plating section.

9. A plating apparatus according to claim 1, further comprising an air discharging system for discharging the air from said plating section.

10. A plating apparatus according to claim 9, wherein said air discharging system discharges the air from said plating section so that the pressure in said plating section is lower than that in said processing section.

11. A plating apparatus according to claim 1, wherein said plating section is enclosed by a partition wall provided in said processing section; and
at least one opening is defined in said partition wall to introduce the substrate into said plating section.

12. A plating apparatus according to claim 1, wherein said plating section has a plurality of plating units disposed adjacent to each other on one side of said second substrate transfer device.

13. A plating apparatus according to claim 1, wherein said second substrate transfer device comprises a mobile-type robot.

14. A plating apparatus according to claim 1, wherein said second substrate transfer device moves the substrate within said plating section.

15. A plating apparatus according to claim 1, wherein said processing unit comprises an annealing unit for heating the substrate.

16. A plating apparatus according to claim 15, wherein said annealing unit and said plating unit are disposed with said second substrate transfer device being interposed therebetween.

17. A plating apparatus according to claim 1, wherein said processing unit comprises a cleaning unit for cleaning a peripheral portion of the substrate.

18. A plating apparatus according to claim 17, wherein said cleaning unit and said plating unit are disposed with said second substrate transfer device being interposed therebetween.

19. A plating apparatus for plating a substrate, comprising:
a processing section having a loading/unloading unit for loading and unloading substrates, at least one processing unit for processing the substrate, a plating section having at least one plating unit for plating the substrate, and a substrate transfer device for transferring the substrate from said loading/unloading unit to said plating unit;
a first air supplying system for supplying air into said processing section; and
a second air supplying system for supplying air into said plating section independently of said first air supplying system,
wherein said processing unit comprises a substrate holder for holding the substrate,
wherein said plating unit comprises a plating container for holding a plating solution therein, and
wherein said transfer device further transfers the substrate to said processing unit.

20. (Cancelled)

21. (Cancelled)

22. (Cancelled)

23. A plating apparatus according to claim 19, wherein said first air supplying system has a fan for supplying air into said processing section.

24. A plating apparatus according to claim 19, wherein said first air supplying system has a circulation pipe for circulating the air in said processing section.

25. A plating apparatus according to claim 19, wherein said second air supplying system has a fan for supplying air into said plating section.

26. A plating apparatus according to claim 19, wherein said second air supplying system has a circulation pipe for circulating the air in said plating section.

27. A plating apparatus according to claim 19, further comprising an air discharging system for discharging the air from said plating section.

28. A plating apparatus according to claim 27, wherein said air discharging system discharges the air from said plating section so that the pressure in said plating section is lower than that in said processing section.

29. A plating apparatus according to claim 19, wherein said plating section is enclosed by a partition wall provided in said processing section; and
at least one opening is defined in said partition wall to introduce the substrate into said plating section.

30. A plating apparatus according to claim 19, wherein said plating section has a plurality of plating units disposed adjacent to each other on one side of said substrate transfer device.

31. A plating apparatus according to claim 19, wherein said substrate transfer device comprises a mobile-type robot.

32. A plating apparatus according to claim 19, wherein said substrate transfer device moves the substrate within said plating section.

33. A plating apparatus according to claim 19, wherein said processing unit comprises an annealing unit for heating the substrate.

34. A plating apparatus according to claim 33, wherein said annealing unit and said plating unit are disposed with said substrate transfer device being interposed therebetween.

35. A plating apparatus according to claim 19, wherein said processing unit comprises a cleaning unit for cleaning a peripheral portion of the substrate.

36. A plating apparatus according to claim 35, wherein said cleaning unit and said plating unit are disposed with said substrate transfer device being interposed therebetween.
